(19) United States
(12) Patent Application Publication
(10) Pub. No.: US 2026/0223436 A1
(43) Pub. Date: Jul. 30, 2026

(54) SEMICONDUCTOR DEVICE

(71) Applicant: FUJI ELECTRIC CO., LTD., Kanagawa (JP)

(72) Inventors: Toru MURAMATSU, Matsumoto-city (JP); Tatsuya NAITO, Matsumoto-city (JP)

(21) Appl. No.: 19/575,874

(22) Filed: Mar. 23, 2026

Related U.S. Application Data
(63) Continuation of application No. PCT/JP2025/004829, filed on Feb. 13, 2025.

(30) Foreign Application Priority Data
Feb. 21, 2024 (JP) 2024-024783

(51) Int. Cl. H10D 84/00; H10D 84/01

(52) U.S. Cl. CPC H10D 84/161; H10D 84/0109

(57) ABSTRACT

Provided is a semiconductor device comprising a transistor portion and a diode portion, the device comprising: a drift region of a first conductivity type, provided in the semiconductor substrate; a plurality of trench portions extending in a predetermined trench extending direction on a front surface side of the semiconductor substrate; a base region of a second conductivity type, provided above the drift region; a first emitter region of the first conductivity type, provided at a front surface of the semiconductor substrate and having a doping concentration higher than that of the drift region; a second emitter region of the first conductivity type, provided at the front surface of the semiconductor substrate and having a doping concentration higher than that of the drift region; and a trench sidewall region of the second conductivity type, provided above the drift region and having a doping concentration higher than that of the base region.

### BACKGROUND

### 1. TECHNICAL FIELD

The present invention relates to a semiconductor device.

### 2. RELATED ART

Conventionally, the semiconductor device including an emitter region of an N type and a contact region of a P type is known (see, for example, Patent Documents 1 and 2).

Patent Document 1: Japanese Patent Application Publication No. 2023-139265

Patent Document 2: Japanese Patent Application Publication No. 2017-059725

### BRIEF DESCRIPTION OF THE DRAWINGS

FIG. 1 shows an example of a top view of a semiconductor device 100.

FIG. 2A is an enlarged view of a region A in FIG. 1.

FIG. 2B illustrates an example of an XZ cross section including an a-a’ cross section in FIG. 2A.

FIG. 2C illustrates an example of an XZ cross section including a b-b’ cross section in FIG. 2A.

FIG. 2D illustrates an example of an XZ cross section including a c-c’ cross section in FIG. 2A.

FIG. 2E shows an example of a YZ cross section including a d-d’ cross section in FIG. 2A.

FIG. 3A is a modification example of an enlarged view of the region A in FIG. 1.

FIG. 3B illustrates an example of an XZ cross section including an e-e’ cross section in FIG. 3A.

FIG. 3C illustrates an example of an XZ cross section including an f-f’ cross section in FIG. 3A.

FIG. 3D illustrates an example of an XZ cross section including a g-g’ cross section in FIG. 3A.

FIG. 3E shows an example of a YZ cross section including a h-h’ cross section in FIG. 3A.

FIG. 3F shows an example of a YZ cross section including an i-i’ cross section in FIG. 3A.

FIG. 4A is an enlarged view of a modification example of an XZ cross section passing through a second emitter formation region 62.

FIG. 4B is an enlarged view of a modification example of an XZ cross section passing through the second emitter formation region 62.

FIG. 4C is an enlarged view of a modification example of an XZ cross section passing through the second emitter formation region 62.

FIG. 4D is an enlarged view of a modification example of an XZ cross section passing through the second emitter formation region 62.

FIG. 4E is an enlarged view of a modification example of an XZ cross section passing through the second emitter formation region 62.

FIG. 4F is an enlarged view of a modification example of an XZ cross section passing through the second emitter formation region 62.

FIG. 4G is an enlarged view of a modification example of an XZ cross section passing through the second emitter formation region 62.

FIG. 5A is an enlarged top view of a modification example of the semiconductor device 100.

FIG. 5B is an enlarged top view of a modification example of the semiconductor device 100.

FIG. 6 illustrates a modification example of an XZ cross section including the e-e’ cross section in FIG. 3A.

FIG. 7 shows an example of a method for manufacturing the semiconductor device 100.

FIG. 8A is a top view of a semiconductor device 500 of a comparative example.

FIG. 8B shows a YZ cross section including a j-j’ cross section in FIG. 8A.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a -Z axis direction are directions opposite to each other. When the Z axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis, respectively. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X axis and the Y axis.

When a term such as “same” or “equal” is used in the present specification, it may encompass a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donors or the acceptors into the semiconductor substrate and turning it into a semiconductor exhibiting a conductivity type of the N type, or a semiconductor exhibiting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D} - N_{A}. In the present specification, the net doping concentration may be simply described as the doping concentration.

In the present specification, when described as a P+ type or an N+ type, it means that a doping concentration is higher than that of a P type or an N type, and when described as a P- type or an N- type, it means that a doping concentration is lower than that of a P type or an N type. In addition, in the present specification, when described as a P++ type or an N++ type, it means that a doping concentration is higher than that of a P+ type or an N+ type.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. A carrier means an electron charge carrier or a hole charge carrier. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

In addition, when a concentration distribution of the donor, acceptor, or net doping has a peak, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like. The carrier concentration becomes lower for the following reason. In the SRP method, a spreading resistance is measured, and a carrier concentration is converted from a measurement value of the spreading resistance. At this time, mobility of the crystalline state is used as the carrier mobility. On the other hand, despite the fact that carrier mobility is decreased at a position where the lattice defect is introduced, the carrier concentration is calculated by using the carrier mobility of the crystalline state. Therefore, a value lower than an actual carrier concentration, i.e., a concentration of donors or acceptors, is obtained.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated. As for numeric representation of power of 10, for example, the representation 1E+16 indicates 1 × 10¹⁶, and the representation 1E-16 indicates 1 × 10⁻¹⁶.

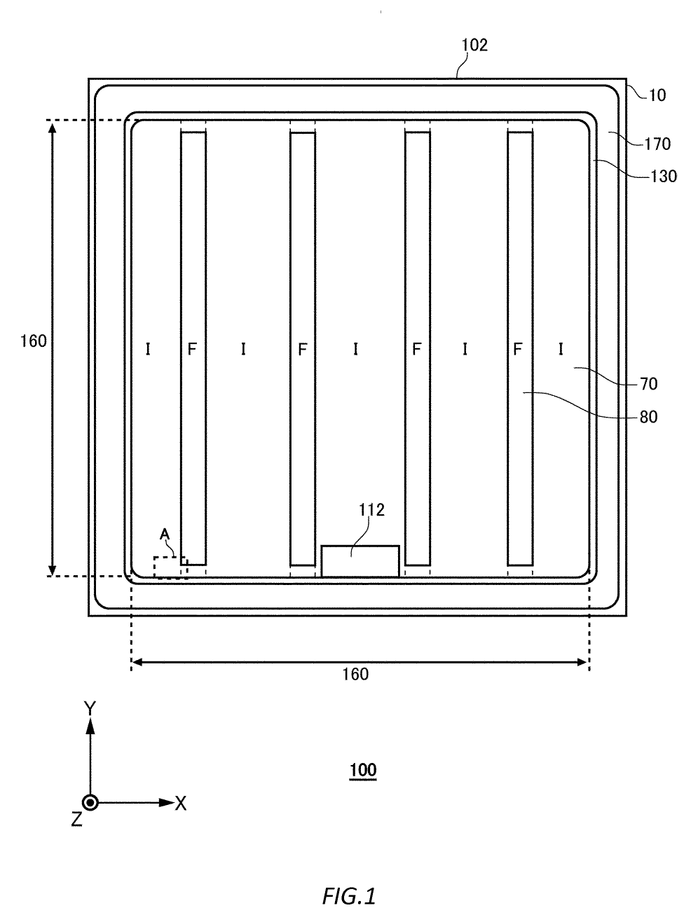

FIG. 1 shows an example of a top view of a semiconductor device 100. FIG. 1 shows positions of respective members projected onto an upper surface of a semiconductor substrate 10. In FIG. 1, only some members of the semiconductor device 100 are shown, and some members are omitted. The semiconductor device 100 is a semiconductor chip including a transistor portion 70 and a diode portion 80.

The transistor portion 70 includes a transistor such as an IGBT (Insulated Gate Bipolar Transistor). The diode portion 80 includes a diode such as a free wheel diode (FWD). The semiconductor device 100 in the present example is a reverse conducting IGBT (RC-IGBT) having the transistor portion 70 and the diode portion 80 on the same chip.

The semiconductor substrate 10 is a substrate that is formed of a semiconductor material. The semiconductor substrate 10 may be a silicon substrate, may be a silicon carbide substrate, may be a diamond substrate, may be a nitride semiconductor substrate such as gallium nitride, may be an inorganic compound semiconductor substrate such as gallium oxide, or may be an organic compound semiconductor substrate. The semiconductor substrate 10 in the present example is the silicon substrate. The semiconductor substrate 10 may be a wafer cut out from a semiconductor ingot, or may be a chip obtained by singulating the wafer. The semiconductor ingot may be manufactured by any of a Czochralski method (CZ method), a magnetic field applied Czochralski method (MCZ method), or a float zone method (FZ method).

The semiconductor substrate 10 has end sides 102 in a top view. When simply referred to as a top view in the present specification, it means that the semiconductor substrate 10 is viewed from an upper surface side. The semiconductor substrate 10 in the present example includes two sets of end sides 102 facing each other in a top view. In FIG. 1, the X axis and the Y axis are parallel to any of the end sides 102. In addition, the Z axis is perpendicular to an upper surface of the semiconductor substrate 10. The semiconductor substrate 10 includes an active region 160 and an edge termination structure portion 170.

The active region 160 is a region in which a main current flows in the depth direction between the upper surface and a lower surface of the semiconductor substrate 10 during an operation of the semiconductor device 100. An emitter electrode is provided above the active region 160, but is omitted in FIG. 1.

In the active region 160, there is provided at least one of the transistor portion 70 which includes a transistor device such as an IGBT, and the diode portion 80 which includes a diode device such as a free wheel diode (FWD). In the example in FIG. 1, the transistor portion 70 and the diode portion 80 are alternately arranged along a predetermined array direction (the X axis direction in the present example) at the upper surface of the semiconductor substrate 10.

In FIG. 1, a region in which each of the transistor portions 70 is arranged is indicated by a symbol "I", and a region in which each of the diode portions 80 is arranged is indicated by a symbol "F". In the present specification, a direction perpendicular to the array direction in a top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is greater than the width in the X axis direction. Similarly, the length of each of the diode portions 80 in the Y axis direction is greater than the width in the X axis direction. The extending direction of the transistor portion 70 and the diode portion 80, and the longitudinal direction of each trench portion, which will be described later, may be the same.

Each of the diode portions 80 includes a cathode region of an N+ type in a region in contact with the lower surface of the semiconductor substrate 10. In the present specification, a region in which the cathode region is provided is referred to as the diode portion 80. In other words, the diode portion 80 is a region that overlaps with the cathode region in a top view. A collector region of the P+ type may be provided in a region other than the cathode region at the lower surface of the semiconductor substrate 10.

The transistor portion 70 has the collector region of the P+ type in a region in contact with the lower surface of the semiconductor substrate 10. In addition, in the transistor portion 70, an emitter region of an N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 in the present example has a gate pad 112. The semiconductor device 100 may have a pad such as an anode pad, a cathode pad, and a current detection pad. Each pad is arranged in the vicinity of an end side 102. The vicinity of the end side 102 refers to a region between the end side 102 and the emitter electrode, in a top view. When the semiconductor device 100 is mounted, each pad may be connected to an external circuit via a wiring such as a wire.

A gate potential is applied to the gate pad 112. The gate pad 112 is electrically connected to a conductive portion of a gate trench portion of the active region 160. The semiconductor device 100 includes a gate runner 130 that connects the gate pad 112 and the gate trench portion.

The gate runner 130 is electrically connected to the gate conductive portion of the transistor portion 70 and applies a gate voltage to the transistor portion 70. The gate runner 130 is provided so as to surround an outer periphery of the active region 160 in a top view. The gate runner 130 is electrically connected to the gate pad 112 provided in the edge termination structure portion 170.

In addition, the semiconductor device 100 may include a temperature sensing unit (not illustrated) that is a PN junction diode formed of polysilicon or the like, and a current detection unit (not illustrated) that simulates an operation of a transistor portion provided in the active region 160.

The semiconductor device 100 in the present example includes the edge termination structure portion 170 between the active region 160 and the end side 102 in a top view. The edge termination structure portion 170 in the present example is arranged between the gate runner 130 and the end side 102. The edge termination structure portion 170 reduces an electric field strength on the upper surface side of the semiconductor substrate 10. The edge termination structure portion 170 may include at least one of a guard ring, a field plate, or a RESURF which is annularly provided to enclose the active region 160.

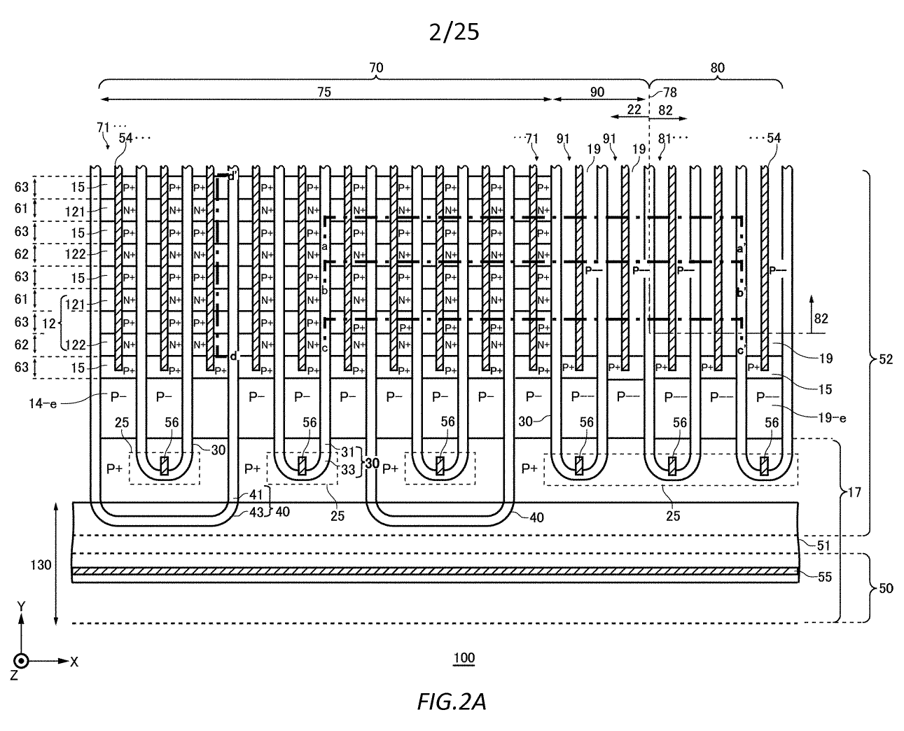

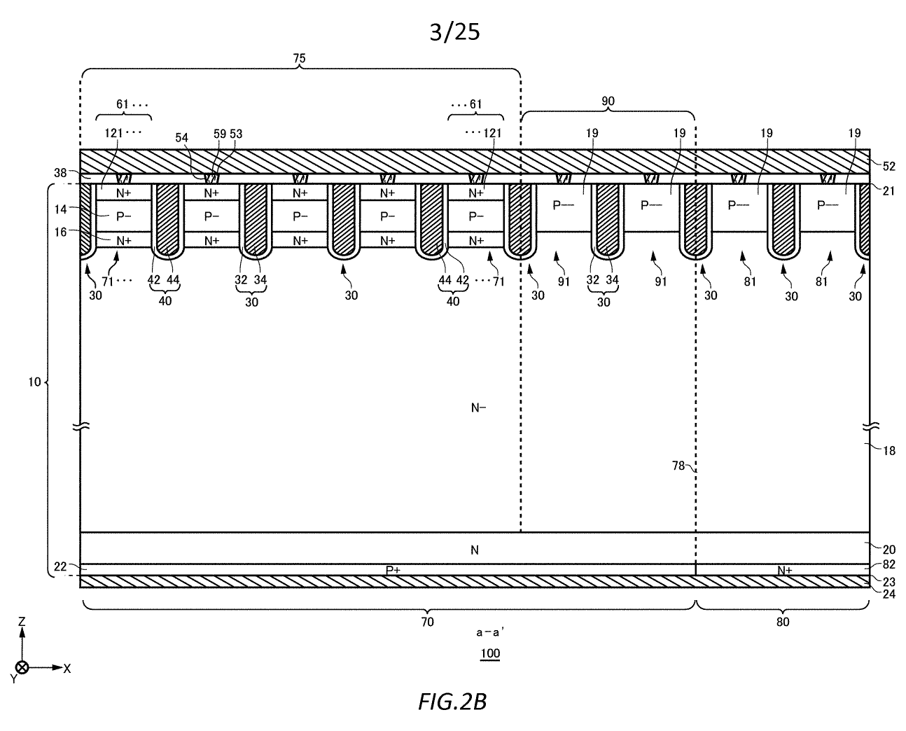

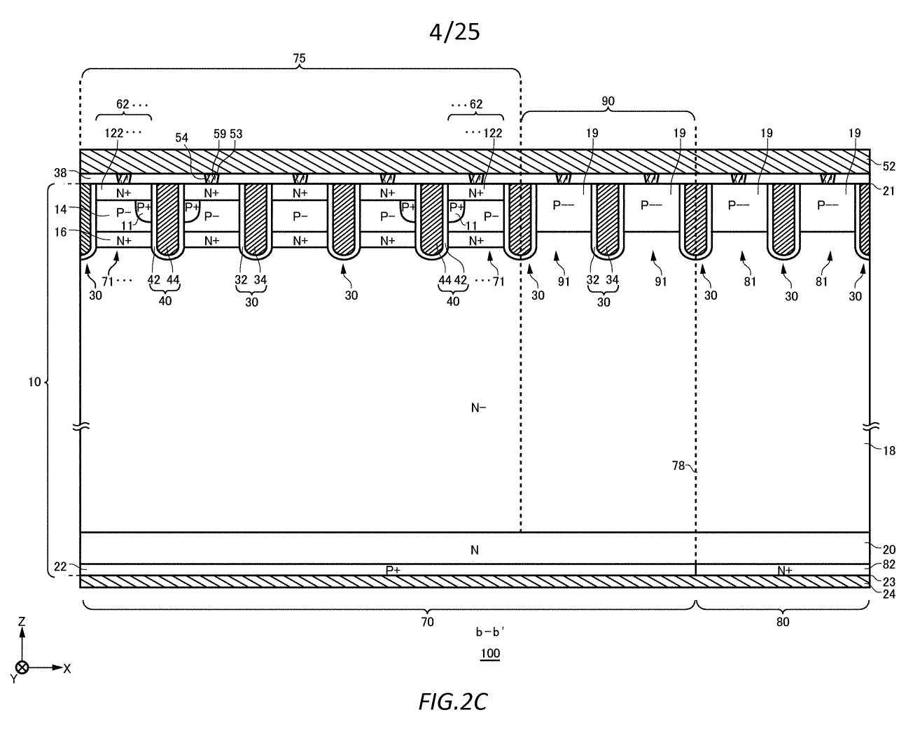

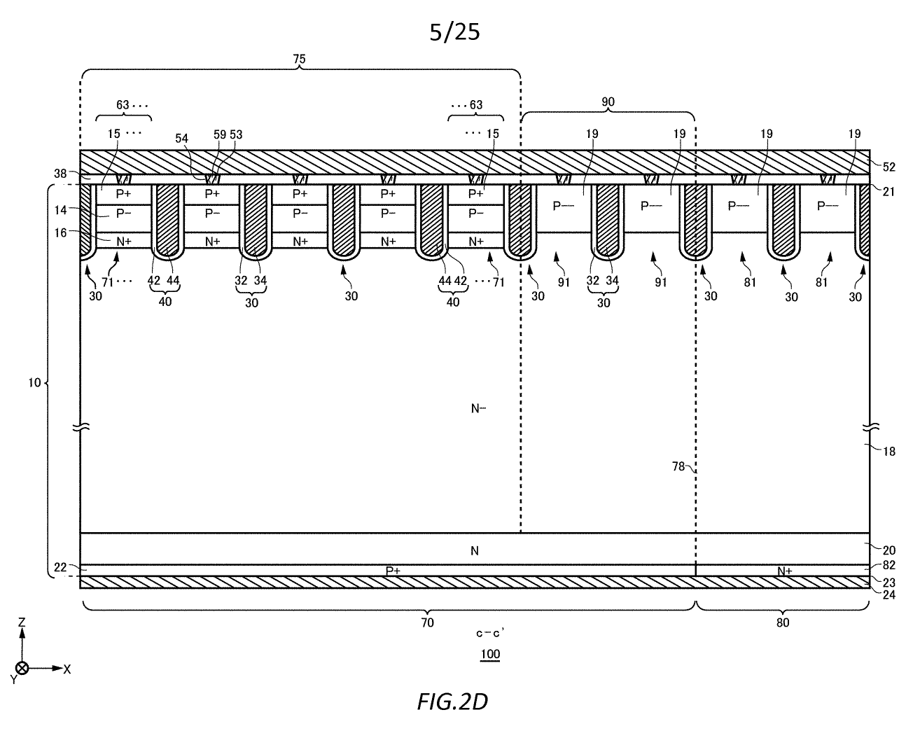

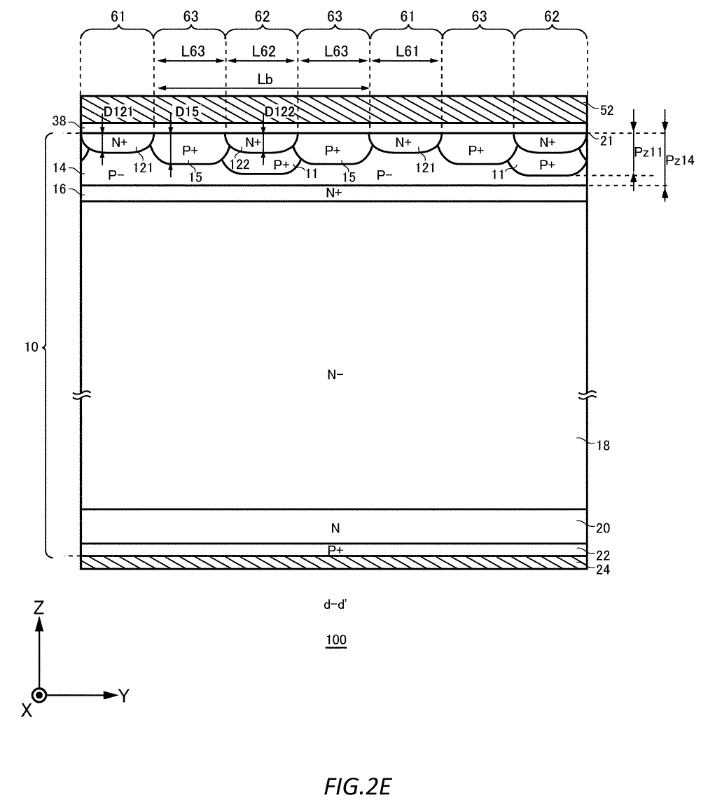

FIG. 2A is an enlarged view of a region A in FIG. 1. The region A is a region including the transistor portion 70, the diode portion 80, and the gate runner 130. The gate runner 130 in the present example includes a gate metal layer 50 and a gate runner portion 51.

A boundary region 90 is provided between the transistor portion 70 and the diode portion 80 at a front surface 21 of the semiconductor substrate 10. The transistor portion 70 has a main region 75 and the boundary region 90. The front surface 21 of the semiconductor substrate 10 refers to one of the two principal surfaces opposite to each other in the semiconductor substrate 10. The front surface 21 will be described later.

The semiconductor device 100 in the present example includes a gate trench portion 40, a dummy trench portion 30, a well region 17, an emitter region 12, a base region 14, a contact region 15, and an anode region 19 that are formed in an interior on a front surface 21 side of the semiconductor substrate 10. In addition, the semiconductor device 100 in the present example includes an emitter electrode 52 and the gate metal layer 50 provided above the front surface 21 of the semiconductor substrate 10. The emitter electrode 52 and the gate metal layer 50 are provided separately from each other.

An interlayer dielectric film is formed between the emitter electrode 52 and the gate metal layer 50, and the front surface 21 of the semiconductor substrate 10, but the interlayer dielectric film is omitted in FIG. 2A. In the interlayer dielectric film in the present example, a contact hole 54, a contact hole 55, and a contact hole 56 are formed to penetrate the interlayer dielectric film.

The emitter electrode 52 is electrically connected, through the contact hole 54 opened in the interlayer dielectric film, to the emitter region 12, the contact region 15, the base region 14, and the anode region 19 at the front surface 21 of the semiconductor substrate 10. In addition, the emitter electrode 52 is connected to a dummy conductive portion inside the dummy trench portion 30 through the contact hole 56. Between the emitter electrode 52 and the dummy conductive portion, a connecting portion 25 formed of a conductive material such as polysilicon doped with an impurity may be provided.

The gate metal layer 50 is in contact with the gate runner portion 51 through the contact hole 55. The gate runner portion 51 is formed of a semiconductor such as polysilicon doped with impurities. The gate runner portion 51 is connected to a gate conductive portion inside the gate trench portion 40 at the front surface 21 of the semiconductor substrate 10.

The emitter electrode 52 and the gate metal layer 50 are formed of a material including metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may have barrier metal formed of titanium, a titanium compound, or the like under a region formed of aluminum and the like. Further, each electrode may include a plug, which is formed by embedding tungsten or the like so as to be in contact with the barrier metal and aluminum or the like, in the contact hole.

The well region 17 is provided so as to overlap with the gate metal layer 50 and the gate runner portion 51. The well region 17 is provided so as to extend at a predetermined width also in a range not overlapping with the gate metal layer 50 and the gate runner portion 51. The well region 17 in the present example is provided away from an end of the contact hole 54 in the Y axis direction toward the gate metal layer 50. The well region 17 is a region of a second conductivity type, having a doping concentration higher than that of the base region 14. The base region 14 in the present example is of the P- type, and the well region 17 is of the P+ type.

Each of the transistor portion 70 and the diode portion 80 includes a plurality of trench portions, which are arrayed at the front surface 21 of the semiconductor substrate 10 in a trench array direction. In the transistor portion 70 in the present example, one or more gate trench portions 40 and one or more dummy trench portions 30 are alternately provided along the trench array direction. In the diode portion 80 in the present example, a plurality of dummy trench portions 30 is provided along the trench array direction. In the diode portion 80 in the present example, the gate trench portion 40 is not provided. It should be noted that the trench array direction may be the same as or different from the array direction of the transistor portion 70 and the diode portion 80. The trench array direction in the present example is the same as the array direction of the transistor portion 70 and the diode portion 80.

In the transistor portion 70, one or more gate trench portions 40 are arrayed at predetermined intervals along the trench array direction. The gate conductive portion inside the gate trench portion 40 is electrically connected to the gate metal layer 50, and a gate potential is applied thereto. In the transistor portion 70, one or more dummy trench portions 30 may be arrayed at predetermined intervals along the trench array direction. A potential different from the gate potential is applied to the dummy conductive portion inside the dummy trench portion 30. The dummy conductive portion in the present example is electrically connected to the emitter electrode 52, and an emitter potential is applied thereto.

In the transistor portion 70, one or more gate trench portions 40 and one or more dummy trench portions 30 may be alternately formed along a predetermined trench array direction. In addition, in the diode portion 80 and the boundary region 90, the dummy trench portions 30 are arrayed at predetermined intervals along the predetermined trench array direction. It should be noted that the transistor portion 70 may alternatively be constituted only by the gate trench portion 40 without the dummy trench portion 30 being provided.

The gate trench portion 40 in the present example may include two extending portions 41 (portions of the trench which are linear along the extending direction) extending along a trench extending direction perpendicular to the trench array direction and a connecting portion 43 connecting the two extending portions 41. The trench extending direction in FIG. 2A is the Y axis direction. It should be noted that the trench extending direction may be the same as or different from the extending direction of the transistor portion 70 and the diode portion 80. The trench extending direction in the present example is the same as the extending direction of the transistor portion 70 and the diode portion 80.

Preferably, at least a part of the connecting portion 43 is provided in a curved shape in a top view. By the connecting portion 43 connecting the end portions of two extending portions 41 in the Y axis direction to each other, it is possible to reduce the electric field strength at the end portions of the extending portions 41.

In the transistor portion 70, the dummy trench portion 30 is provided between the respective extending portions 41 of the gate trench portion 40. One dummy trench portion 30 may be provided or a plurality of dummy trench portions 30 may be provided between the respective extending portions 41. The dummy trench portion 30 may have a linear shape extending in a predetermined trench extending direction, and may include an extending portion 31 and a connecting portion 33 similarly to the gate trench portion 40. The semiconductor device 100 may include both of the linear dummy trench portion 30 having no connecting portion 33 and the dummy trench portion 30 having the connecting portion 33. A direction in which an extending portion 41 of the gate trench portion 40 or the extending portion 31 of the dummy trench portion 30 extends long in the trench extending direction is defined as the longitudinal direction of the trench portion. The longitudinal direction of the gate trench portion 40 or the dummy trench portion 30 may coincide with the extending direction of the transistor portion 70 and the diode portion 80. In the present example, the extending direction of the transistor portion 70 and the diode portion 80 and the longitudinal direction of the trench portion are the Y axis direction. The trench array direction in which a plurality of the gate trench portions 40 or a plurality of the dummy trench portions 30 are arrayed is defined as a lateral direction of the trench portion. The lateral direction may coincide with the array direction of the transistor portion 70 and the diode portion 80. In addition, the lateral direction may be perpendicular to the longitudinal direction. In the present example, the longitudinal direction and the lateral direction are perpendicular to each other. In the present example, the array direction of the transistor portion 70 and the diode portion 80 and the lateral direction of the trench portion are the X axis direction.

In the connecting portion 43 at an edge of the gate trench portion 40, the gate conductive portion inside the gate trench portion 40 is connected to the gate runner portion 51. The gate trench portion 40 may be provided so as to protrude to the gate runner portion 51 side with respect to the dummy trench portion 30 in the trench extending direction (Y axis direction). The protruding portion of the gate trench portion 40 is connected to the gate runner portion 51.

A diffusion depth of the well region 17 may be deeper than depths of the gate trench portion 40 and the dummy trench portion 30. The end portions in the Y axis direction of the gate trench portion 40 and the dummy trench portion 30 are provided in the well region 17 in a top view. In other words, a bottom portion in the depth direction of each trench portion is covered with the well region 17 at an end portion in the Y axis direction of each trench portion. With this configuration, the electric field strength on the bottom portion of each trench portion can be reduced.

A mesa portion is provided between the respective trench portions in the array direction. The mesa portion refers to a region interposed between two adjacent trench portions within the semiconductor substrate 10. As an example, an upper end of the mesa portion is the upper surface of the semiconductor substrate 10. The depth position of the lower end of the mesa portion is the same as the depth position of a lower end of the trench portion. The mesa portion in the present example is provided at the upper surface of the semiconductor substrate 10, so as to extend in the trench extending direction (Y axis direction) along the trench portion.

The main region 75 is a region in which a main current flows in the depth direction in the transistor portion 70. The main region 75 has the emitter region 12. The main region 75 has a first emitter formation region 61 and a second emitter formation region 62. The main region 75 in the present example has the first emitter formation region 61, the second emitter formation region 62, and a contact formation region 63. An area of the main region 75 may be larger than an area of the boundary region 90.

The boundary region 90 is provided on the diode portion 80 side in the transistor portion 70. That is, in the transistor portion 70, the boundary region 90 is provided adjacent to the diode portion 80 rather than the main region 75. The boundary region 90 may be a region having the dummy trench portion 30 and provided with a collector region 22 on the back surface side of the semiconductor substrate 10. Each of both ends in the trench array direction, of the mesa portion included in the boundary region 90 may be in contact with the dummy trench portion 30. The trench portions of the boundary region 90 may be all dummy trench portions 30. The boundary region 90 may include the gate trench portion 40. In the boundary region 90 in the present example, the emitter region 12 of a first conductivity type is not provided in the mesa portion on the front surface 21 side of the semiconductor substrate 10. The boundary region 90 may have the base region 14, or may have the anode region 19 at the front surface 21. The boundary region 90 may have the emitter region 12 or the contact region 15 at the front surface 21. The boundary region 90 in the present example has the anode region 19 and the contact region 15 at the front surface 21. It should be noted that FIG. 2A shows the positions of the collector region 22 and the cathode region 82 provided on the back surface side of the semiconductor substrate 10 when projected on the front surface 21 side.

A mesa portion 71 is a mesa portion provided in the main region 75 of the transistor portion 70. A mesa portion 81 is a mesa portion provided in the diode portion 80. A mesa portion 91 is a mesa portion provided in the boundary region 90. When simply referred to as a mesa portion in the present specification, it may refer to each of the mesa portion 71, the mesa portion 81, or the mesa portion 91. The extending portions of each trench portion may be regarded as one trench portion. That is, the region sandwiched between two extending portions may be set to be a mesa portion.

Each mesa portion is provided with the base region 14 or the anode region 19. Among base regions 14 or anode regions 19 that are exposed on the front surface 21 of the semiconductor substrate 10 in the mesa portion, a region arranged closest to the gate metal layer 50 is defined as a base region 14-e or an anode region 19-e. In FIG. 2A, the base region 14-e or the anode region 19-e arranged at one end portion of each mesa portion in the trench extending direction is shown, but the base region 14-e or the anode region 19-e is also arranged at another end portion of each mesa portion. In each mesa portion, at least one of the emitter region 12 of the first conductivity type or the contact region 15 of the second conductivity type may be provided in a region sandwiched between base regions 14-e or anode regions 19-e in a top view. The emitter region 12 in the present example is of the N+ type, and the contact region 15 is of the P+ type. The emitter region 12 and the contact region 15 may be provided between the base region 14 and the upper surface of the semiconductor substrate 10 in the depth direction.

The mesa portion 71 of the transistor portion 70 includes the emitter region 12 exposed on the front surface 21 of the semiconductor substrate 10. The emitter region 12 is provided in contact with the gate trench portion 40. The mesa portion 71 may be provided with the contact region 15 exposed on the front surface 21 of the semiconductor substrate 10.

The mesa portion 71 in the present example has the first emitter formation region 61, the second emitter formation region 62, and the contact formation region 63. The mesa portion 71 is an example of a first mesa portion having the first emitter formation region 61 and the second emitter formation region 62. The first emitter formation region 61 is a region in which a trench sidewall region 11, which will be described later, is not provided, and may form a channel. The second emitter formation region 62 is a region in which the trench sidewall region 11 is provided, and may not form a channel. The trench sidewall region 11 will be described later.

The first emitter formation region 61 is a region in which a first emitter region 121 is provided at a sidewall of the gate trench portion 40. In addition, the first emitter formation region 61 may be a region in which the trench sidewall region 11 is not provided at the sidewall of the gate trench portion 40 below the first emitter region 121. The first emitter formation region 61 is a region in which, when the gate is turned on, an inversion layer is formed and electrons are injected. The first emitter formation region 61 may be in contact with at least one of the second emitter formation region 62 or the contact formation region 63. In the present example, in the trench extending direction, both ends of the first emitter formation region 61 are in contact with contact formation regions 63. This allows holes to be extracted at both ends of the first emitter formation region 61.

The first emitter region 121 is a region of the first conductivity type, provided at the front surface 21 of the semiconductor substrate 10 and having a doping concentration higher than that of a drift region 18. The drift region 18 will be described later. Doping concentrations of the first emitter region 121 and a second emitter region 122 may be 1E21 cm⁻³ or more and 1E22 cm⁻³ or less. The first emitter region 121 and the second emitter region 122 may have the same doping concentration. The first emitter region 121 in the present example extends, in the trench array direction, from one trench portion that is in contact with the mesa portion 71 to another trench portion that faces the one trench portion.

The second emitter formation region 62 is a region in which the trench sidewall region 11 is provided at the sidewall of the gate trench portion 40 below the second emitter region 122. Since the second emitter formation region 62 has the trench sidewall region 11 below the second emitter region 122, an inversion layer is not formed, and the second emitter formation region 62 may not function as a channel region. The second emitter formation region 62 may be in contact with at least one of the first emitter formation region 61 or the contact formation region 63. In the present example, in the trench extending direction, both ends of the second emitter formation region 62 are in contact with contact formation regions 63.

The second emitter region 122 is a region of the first conductivity type, provided at the front surface 21 of the semiconductor substrate 10 and having a doping concentration higher than that of the drift region 18. The second emitter region 122 in the present example extends, in the trench array direction, from one trench portion that is in contact with the mesa portion 71 to another trench portion that faces the one trench portion.

The doping concentration of the first emitter region 121 may be the same as a doping concentration of the second emitter region 122. That is, the first emitter region 121 and the second emitter region 122 may be formed by an ion implantation process under the same condition. The first emitter region 121 and the second emitter region 122 may be simultaneously formed in the ion implantation process under the same condition. An integrated value obtained by integrating the doping concentration of the first emitter region 121 may be the same as an integrated value obtained by integrating the doping concentration of the second emitter region 122.

The contact formation region 63 is a region in which the contact region 15 is provided at the front surface 21. The contact formation region 63 may be in contact with at least one of the first emitter formation region 61 or the second emitter formation region 62.

The first emitter formation region 61, the second emitter formation region 62, and the contact formation region 63 may be arranged in any order in the trench extending direction. In the present example, in the trench extending direction, the first emitter formation region 61, the contact formation region 63, the second emitter formation region 62, and the contact formation region 63 are repeatedly provided in this order.

The contact formation region 63 is in contact with at least one of the first emitter formation region 61 or the second emitter formation region 62. The contact formation region 63 in the present example is in contact with both the first emitter formation region 61 and the second emitter formation region 62. In the present example, in the trench extending direction, one end of the contact formation region 63 is in contact with the first emitter formation region 61, and another end of the contact formation region 63 is in contact with the second emitter formation region 62.

In the mesa portion 81 of the diode portion 80, the emitter region 12 is not provided, but the emitter region 12 may be provided. The anode region 19 is provided at the front surface 21 of the mesa portion 81 in the present example. The contact region 15 may be provided at the front surface 21 of the mesa portion 81. In a region sandwiched between the anode regions 19-e at the front surface 21 of the mesa portion 81, the contact region 15 may be provided in contact with each of the anode regions 19-e. In a region sandwiched between contact regions 15 at the front surface 21 of the mesa portion 81, the anode region 19 may be provided. The anode region 19 may be arranged over an entirety of the region sandwiched between the contact regions 15 in the trench extending direction.

The contact hole 54 is provided above each mesa portion. The contact hole 54 is arranged in a region sandwiched between the base regions 14-e or the anode regions 19-e along the trench extending direction. The contact hole 54 in the present example is provided above respective regions of the contact region 15, the base region 14, the anode region 19, and the emitter region 12. The contact hole 54 is not provided in regions corresponding to the base region 14-e, the anode region 19-e, and the well region 17. The contact hole 54 may be arranged at the center of the mesa portion 71 in the trench array direction (X axis direction).

In the diode portion 80, a cathode region 82 of the N+ type is provided in a region in direct contact with the lower surface of the semiconductor substrate 10. A doping concentration of the cathode region 82 is higher than a doping concentration of the drift region 18. At the lower surface of the semiconductor substrate 10, a collector region of the P+ type 22 may be provided in a region in which the cathode region 82 is not provided. The cathode region 82 and the collector region 22 are provided between a back surface 23 of the semiconductor substrate 10 and a buffer region 20, which will be described later. In FIG. 2A, a boundary 78 between the cathode region 82 and the collector region 22 is indicated by a broken line. The back surface 23 will be described later.

The cathode region 82 is arranged away from the well region 17 in the Y axis direction. With this configuration, a distance between a region of the P type (well region 17) having a relatively high doping concentration and formed up to a deep position and the cathode region 82 can be secured to improve a breakdown voltage and suppress hole injection from the well region 17. An end portion in the Y axis direction of the cathode region 82 in the present example is arranged farther away from the well region 17 than an end portion in the Y axis direction of the contact hole 54. In another example, the end portion in the Y axis direction of the cathode region 82 may be arranged between the well region 17 and the contact hole 54.

The anode region 19 is provided in the mesa portion 91 of the boundary region 90. The boundary region 90 may include a plurality of mesa portions 91. The mesa portion 91 may have the base region 14 instead of the anode region 19. The anode region 19 will be described later.

FIG. 2B illustrates an example of an XZ cross section including an a-a’ cross section in FIG. 2A. The XZ cross section including the a-a’ cross section is an XZ plane passing through the first emitter formation region 61 in the transistor portion 70. The semiconductor device 100 in the present example has the semiconductor substrate 10, an interlayer dielectric film 38, the emitter electrode 52, and a collector electrode 24 in the XZ cross section including the a-a’ cross section. The emitter electrode 52 is provided above the semiconductor substrate 10 and the interlayer dielectric film 38.

The drift region 18 is a region of the first conductivity type which is provided in the semiconductor substrate 10. The drift region 18 in the present example is of the N- type as an example. The drift region 18 may be a region which has remained without other doping regions formed in the semiconductor substrate 10. That is, the doping concentration of the drift region 18 may be a doping concentration of the semiconductor substrate 10.

The buffer region 20 is a region of the first conductivity type which is provided on a back surface 23 side of the semiconductor substrate 10 with respect to the drift region 18. The buffer region 20 in the present example is provided closer to the back surface 23 of the semiconductor substrate 10 than a center of the semiconductor substrate 10 in the depth direction. The buffer region 20 in the present example is of the N type as an example. A doping concentration in the buffer region 20 is higher than the doping concentration in the drift region 18. The buffer region 20 may function as a field stop layer which prevents a depletion layer expanding from a lower surface side of the base region 14 from reaching the collector region 22 of the second conductivity type and the cathode region 82 of the first conductivity type.

The collector region 22 and the cathode region 82 are provided at the back surface 23 of the semiconductor substrate 10. The collector region 22 is provided below the buffer region 20 in the transistor portion 70. The cathode region 82 is provided below the buffer region 20 in the diode portion 80. The boundary 78 between the collector region 22 and the cathode region 82 may be a boundary between the transistor portion 70 and the diode portion 80.

The collector electrode 24 is formed at the back surface 23 of the semiconductor substrate 10. The collector electrode 24 is formed of a conductive material such as metal. At least a partial region of the collector electrode 24 may be formed of metal such as aluminum (Al) or a metal alloy such as an aluminum-silicon alloy (AlSi) or an aluminum-silicon-copper alloy (AlSiCu).

The base region 14 is a region of the second conductivity type which is provided in the mesa portion 71 above the drift region 18. The base region 14 may also be provided in the mesa portion 91. The base region 14 is provided in contact with the gate trench portion 40. The base region 14 may be provided in contact with the dummy trench portion 30.

The anode region 19 is a region of the second conductivity type, provided in the mesa portion 91 and the mesa portion 81 above the drift region 18. The anode region 19 is provided in contact with the dummy trench portion 30. The anode region 19 may be provided in contact with the gate trench portion 40. A depth of the anode region 19 may be deeper, shallower, or equal to a depth of the base region 14 in the depth direction of the semiconductor substrate 10. The depth of the anode region 19 in the present example is equal to the depth of the base region 14.

A doping concentration of the anode region 19 may be the same as that of the base region 14, or may be lower than that of the base region 14. The anode region 19 in the present example is of the P-- type. The maximum value of the doping concentration of the anode region 19 may be smaller than or may be equal to the maximum value of a doping concentration of the base region 14. The maximum value of the doping concentration of the anode region 19 in the present example is smaller than the maximum value of the doping concentration of the base region 14. The integrated value obtained by integrating the doping concentration of the anode region 19 along the depth direction of the semiconductor substrate 10 may be smaller than or may be equal to the integrated value obtained by integrating the doping concentration of the base region 14. The integrated value of the doping concentration of the anode region 19 in the present example is smaller than the integrated value of the doping concentration of the base region 14.

The first emitter region 121 is provided on the front surface 21 side with respect to the drift region 18, and has a doping concentration higher than that of the drift region 18. The first emitter region 121 in the present example is provided at the front surface 21. That is, the first emitter region 121 in the present example is exposed on the front surface 21 of the semiconductor substrate 10. The first emitter region 121 in the present example is provided in the mesa portion 71 above the base region 14. At the sidewall of the gate trench portion 40 of the first emitter formation region 61, the base region 14 may be in contact with the first emitter region 121. The first emitter region 121 may be provided in contact with the gate trench portion 40. The first emitter region 121 may be or may not be in contact with the dummy trench portion 30. It should be noted that the first emitter region 121 may not be provided in the mesa portion 91.

An accumulation region 16 is provided above the drift region 18. That is, the accumulation region 16 is provided on the front surface 21 side of the semiconductor substrate 10 with respect to the drift region 18. The accumulation region 16 is a region of the first conductivity type which has a doping concentration higher than that of the drift region 18. The accumulation region 16 in the present example is of the N+ type as an example. A doping concentration of the accumulation region 16 may be 1E16 cm⁻³ or more and 1E18 cm⁻³ or less. The accumulation region 16 is provided in the mesa portion 71. The accumulation region 16 may also be provided in the mesa portion 81 and the mesa portion 91.

In addition, the accumulation region 16 is provided in contact with the gate trench portion 40. At the sidewall of the gate trench portion 40 of the first emitter formation region 61, the accumulation region 16 may be in contact with the base region 14. The accumulation region 16 may be or may not be in contact with the dummy trench portion 30. The doping concentration of the accumulation region 16 is higher than the doping concentration of the drift region 18. Providing the accumulation region 16 can enhance the carrier injection enhancement effect (IE effect) to reduce an ON voltage of the transistor portion 70.

One or more gate trench portions 40 and one or more dummy trench portions 30 are provided at the front surface 21. Each trench portion is provided from the front surface 21 to the drift region 18. In a region in which at least any of the emitter region 12, the base region 14, the contact region 15, or the accumulation region 16 is provided, each trench portion also penetrates through these regions to reach the drift region 18. The configuration of the trench portion penetrating the doping region is not limited to the one manufactured in an order in which the doping region is formed and then the trench portion is formed. The configuration of the trench portions penetrating the doping region also includes a configuration of forming the trench portions and thereafter forming the doping region between the trench portions.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inward of the gate dielectric film 42 within the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 at the front surface 21.

The gate conductive portion 44 includes a region facing the base region 14 with the gate dielectric film 42 interposed therebetween. When a predetermined voltage is applied to the gate conductive portion 44, a channel of electrons by an inversion layer is formed in a surface layer of an interface which is in contact with the gate trench in the base region 14.

The dummy trench portion 30 may have the same structure as the gate trench portion 40. The dummy trench portion 30 has a dummy trench, a dummy dielectric film 32, and a dummy conductive portion 34 which are formed on the front surface 21 side. The dummy dielectric film 32 is formed covering the inner walls of the dummy trench. The dummy conductive portion 34 is formed inside the dummy trench, and is formed inward of the dummy dielectric film 32. The dummy dielectric film 32 insulates the dummy conductive portion 34 from the semiconductor substrate 10. The dummy trench portion 30 is covered by the interlayer dielectric film 38 at the front surface 21.

The interlayer dielectric film 38 is provided at the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and the contact hole 56 may be provided to penetrate through the interlayer dielectric film 38.

A barrier metal 53 is provided on a sidewall and a bottom surface of the contact hole 54. The barrier metal 53 may be provided over an entirety of the bottom surface of the contact hole 54. A material of the barrier metal 53 may be titanium or a titanium compound. When the semiconductor substrate 10 is silicon, the barrier metal 53 may react with the semiconductor substrate 10 to form a silicide.

A plug portion 59 is provided in the contact hole 54 inside the barrier metal 53. A material of the plug portion 59 may be tungsten. The material of the plug portion 59 may be the same as a material of the emitter electrode 52.

The semiconductor device 100 in the present example does not include a lifetime control unit having a lifetime killer, but may include the lifetime control unit. The semiconductor device 100 may include a lifetime killer region on the front surface 21 side with respect to the center of the semiconductor substrate 10 in the depth direction, or may include the lifetime killer region on the back surface 23 side with respect to the center of the semiconductor substrate 10 in the depth direction.

FIG. 2C illustrates an example of an XZ cross section including a b-b’ cross section in FIG. 2A. The XZ cross section including the b-b’ cross section is an XZ plane passing through the second emitter formation region 62 in the transistor portion 70. In the present example, points different from the a-a’ cross section in FIG. 2B passing through the first emitter formation region 61, will be particularly described. Other points may be the same as those of the a-a’ cross section in FIG. 2B.

The second emitter formation region 62 has, in the mesa portion 71, the second emitter region 122, the trench sidewall region 11, the base region 14, and the accumulation region 16. The second emitter formation region 62 does not have the contact region 15.

The second emitter region 122 is provided on the front surface 21 side with respect to the drift region 18, and has a doping concentration higher than that of the drift region 18. The second emitter region 122 in the present example is provided at the front surface 21. That is, the second emitter region 122 in the present example is exposed on the front surface 21 of the semiconductor substrate 10. The second emitter region 122 in the present example is provided in the mesa portion 71 above the base region 14. The second emitter region 122 may be provided above the trench sidewall region 11. A lower surface of the second emitter region 122 may be in contact with an upper surface of the base region 14. The lower surface of the second emitter region 122 may be in contact with an upper surface of the trench sidewall region 11. The second emitter region 122 may be provided in contact with the gate trench portion 40. The second emitter region 122 may be or may not be in contact with the dummy trench portion 30. It should be noted that the second emitter region 122 may not be provided in the mesa portion 91.

The trench sidewall region 11 is a region of the second conductivity type, provided above the drift region 18 and having a doping concentration higher than that of the base region 14. The trench sidewall region 11 may be provided above the accumulation region 16. A doping concentration of the trench sidewall region 11 may be lower than a doping concentration of the contact region 15. The doping concentration of the trench sidewall region 11 may be 1E17 cm⁻³ or more and 1E20 cm⁻³ or less. It should be noted that the doping concentration of the trench sidewall region 11 may be the same as that of the contact region 15.

The trench sidewall region 11 is in contact with the gate trench portion 40. The trench sidewall region 11 may be or may not be in contact with the dummy trench portion 30. The trench sidewall region 11 in the present example is in contact with a lower end of the second emitter region 122. The trench sidewall region 11 in the present example is provided spaced apart from the accumulation region 16. The trench sidewall region 11 may be in contact with the accumulation region 16. The trench sidewall region 11 may not be provided in the diode portion 80 and the boundary region 90.

FIG. 2D illustrates an example of an XZ cross section including a c-c’ cross section in FIG. 2A. The XZ cross section including the c-c’ cross section is an XZ plane passing through the contact formation region 63 in the transistor portion 70. In the present example, points different from the a-a’ cross section in FIG. 2B passing through the first emitter formation region 61, will be particularly described. Other points may be the same as those of the a-a’ cross section in FIG. 2B.

The contact region 15 is a region of the second conductivity type, having a doping concentration higher than that of the base region 14. The doping concentration of the contact region 15 may be 1E21 cm⁻³ or more and 1E22 cm⁻³ or less. The contact region 15 is provided above the base region 14. The contact region 15 is provided above the accumulation region 16. The contact region 15 may extend, in the contact formation region 63, in the trench array direction from one of two adjacent trench portions to another of the two adjacent trench portions. The trench sidewall region 11 may not be provided below the contact region 15.

FIG. 2E shows an example of a YZ cross section including a d-d’ cross section in FIG. 2A. The YZ cross section including the d-d’ cross section is a YZ plane passing through the mesa portion 71 of the transistor portion 70. The d-d’ cross section is a cross section that does not pass through the contact hole 54.

The first emitter formation region 61 is provided between two adjacent contact formation regions 63 in the trench extending direction. The second emitter formation region 62 is provided between two adjacent contact formation regions 63 in the trench extending direction. That is, in the trench extending direction, the contact formation regions 63 may be provided so as to sandwich both ends of the first emitter formation region 61, and may be provided so as to sandwich both ends of the second emitter formation region 62.

A length L61 is a width of the first emitter formation region 61 in the trench extending direction. The length L61 may be a width, in the trench extending direction, of the first emitter formation region 61 that is in contact with the gate trench portion 40. The length L61 may be greater than a length L63, or may be the same as a length L63. The length L61 of the first emitter formation region 61 in the trench extending direction may be 0.5 μm or more and 3.0 μm or less. A region in which a channel is formed can be adjusted by the length L61. The length L61 may be adjusted in consideration of easiness of extracting holes or the like.

A length L62 is a width of the second emitter formation region 62 in the trench extending direction. The length L62 may be a width, in the trench extending direction, of the second emitter formation region 62 that is in contact with the gate trench portion 40. The length L62 of the second emitter formation region 62 in the trench extending direction may be 0.5 μm or more and 3.0 μm or less.

The length L62 may be the same as or different from the length L61. The length L62 may be greater than or smaller than the length L61. Increasing the length L62 can increase a region in which no channel is formed, while suppressing an amount of hole injection into the diode portion 80.

The length L63 is a width of the contact formation region 63 in the trench extending direction. The length L63 may be a width, in the trench extending direction, of the contact formation region 63 that is in contact with the gate trench portion 40. The length L63 may be the same as or different from the length L61 and the length L62. The length L63 may be greater than or smaller than the length L61 and the length L62. The length L63 may be 0.5 μm or more and 5.0 μm or less.

A length Lb is a length, in the trench extending direction, of a region in which no channel is formed at the sidewall of the gate trench portion 40. The length Lb in the present example is a width, in the trench extending direction, of a region consisting of the second emitter formation region 62 and the contact formation regions 63 provided at both ends of the second emitter formation region 62. The length Lb may be greater than or equal to the length L61. A ratio between the length L61 and the length Lb, which determines a channel density, may be determined according to a saturation current required for the semiconductor device 100.

A thickness D121 is a width of the first emitter region 121 in the depth direction of the semiconductor substrate 10. When the first emitter region 121 has an inclination at a lower surface thereof, the thickness D121 may be a width of the first emitter region 121 at a shallowest position of the first emitter region 121. The thickness D121 may be 0.3 μm or more and 0.7 μm or less.

A thickness D122 is a width of the second emitter region 122 in the depth direction of the semiconductor substrate 10. When the second emitter region 122 has an inclination at a lower surface thereof, the thickness D122 may be a width of the second emitter region 122 at a shallowest position of the second emitter region 122. The thickness D122 may be 0.3 μm or more and 0.7 μm or less.

The thickness D121 may be the same as or different from the thickness D122. The thickness D121 may be greater than the thickness D122. That is, a lower end of the first emitter region 121 may be deeper than the lower end of the second emitter region 122. A dopant of the second emitter region 122 may be less likely to diffuse than a dopant of the first emitter region 121 due to an influence of the trench sidewall region 11. In this case, the second emitter region 122 may be formed shallower than the first emitter region 121.

A thickness D15 is a width of the contact region 15 in the depth direction of the semiconductor substrate 10. When the contact region 15 has an inclination at a lower surface thereof, the thickness D15 may be a width of the contact region 15 at a shallowest position of the contact region 15. The thickness D15 may be greater than the thickness D121 and the thickness D122. The thickness D15 may be 0.5 μm or more and 2.0 μm or less.

A distance Pz14 is a distance from the front surface 21 to a lower end of the base region 14 in the depth direction of the semiconductor substrate 10. The distance Pz14 may be 2.0 μm or more and the 5.0 μm or less.

A distance Pz11 is the distance from the front surface 21 to a lower end of the trench sidewall region 11 in the depth direction of the semiconductor substrate 10. The distance Pz11 may be 2.0 μm or more and 4.0 μm or less. The distance Pz11 may be smaller than the distance Pz14. That is, the lower end of the trench sidewall region 11 may be shallower than the lower end of the base region 14.

Here, a reverse recovery loss Err of the semiconductor device 100 and a forward voltage Vf of the diode portion 80 are in a trade-off relationship. The semiconductor device 100 in the present example can reduce the reverse recovery loss Err by adjusting the amount of hole injection from the transistor portion 70 into the diode portion 80 while maintaining the channel density. The semiconductor device 100 in the present example can control the channel density according to a proportion of the first emitter formation region 61 that is provided, and adjust the amount of hole injection by the trench sidewall region 11 provided in the second emitter formation region 62, and thus can more flexibly control characteristics of the semiconductor device 100.

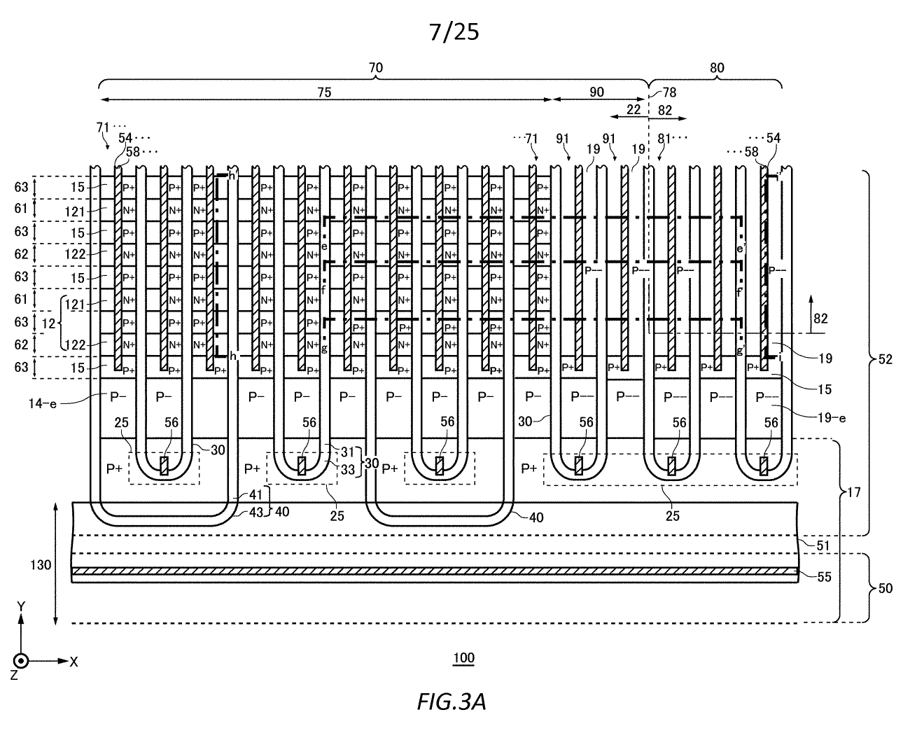

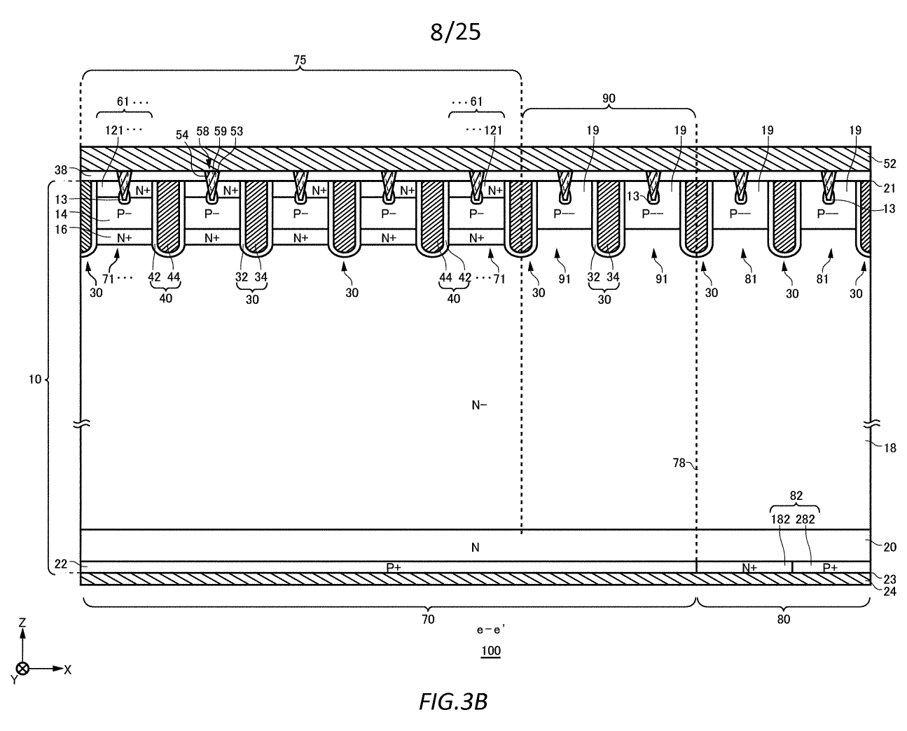

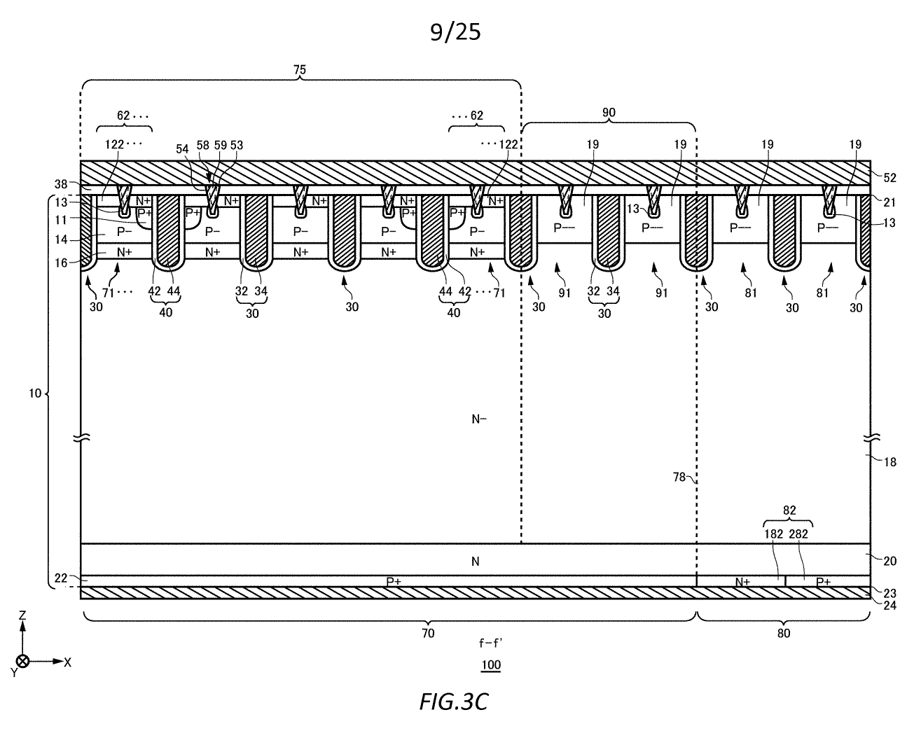

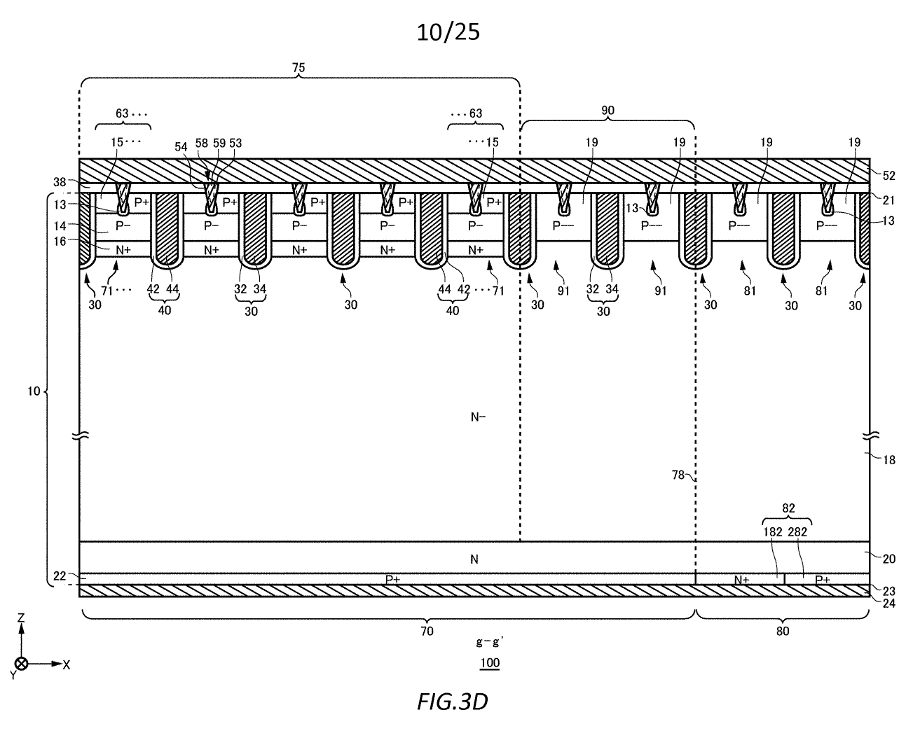

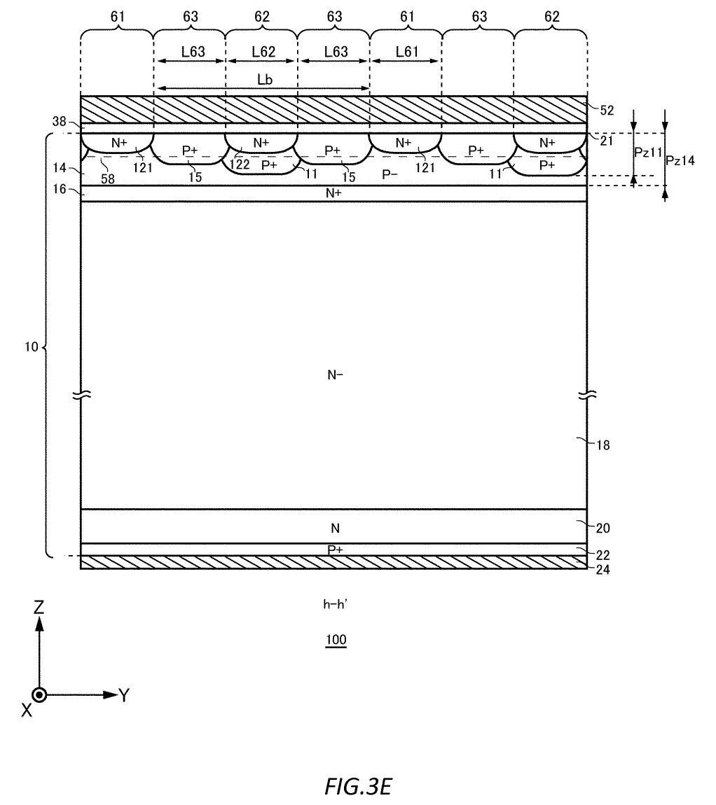

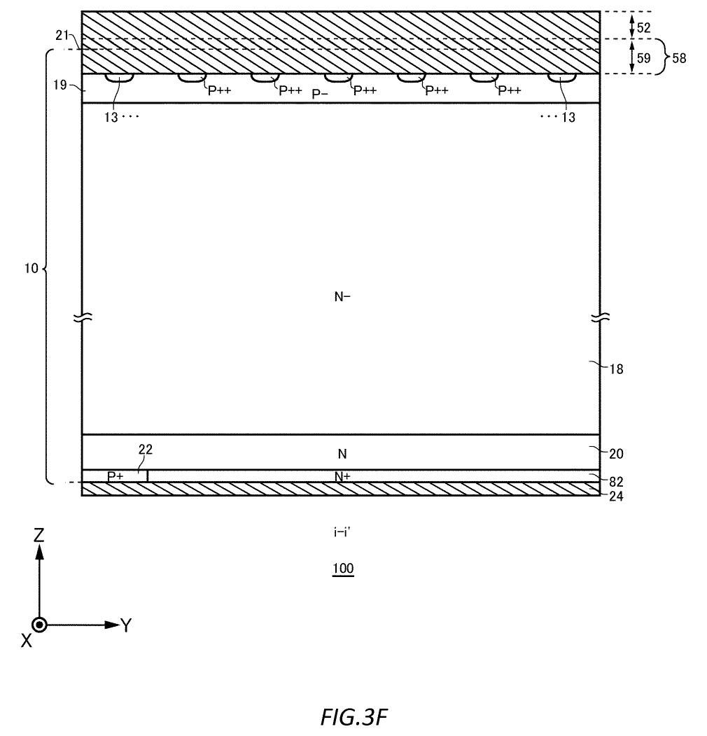

FIG. 3A is a modification example of an enlarged view of the region A in FIG. 1. The semiconductor device 100 in the present example is different from the semiconductor device 100 in FIG. 2A in that it includes a trench contact portion 58. In the present example, points different from the semiconductor device 100 in FIG. 2A will be particularly described. Other points may be the same as those of the semiconductor device 100 in FIG. 2A.

The trench contact portion 58 is provided in a mesa portion between two adjacent trench portions among a plurality of trench portions. The trench contact portion 58 extends from the front surface of the semiconductor substrate 10 in the depth direction of the semiconductor substrate 10. The trench contact portion 58 may be provided so as to extend from an upper end of the interlayer dielectric film 38 to an inside of the semiconductor substrate 10. The trench contact portion 58 in the present example is provided in the contact hole 54. Since the semiconductor device 100 in the present example includes the trench contact portion 58, it is possible to lower a base resistance during turn-off and improve a latch-up tolerance.

FIG. 3B illustrates an example of an XZ cross section including an e-e’ cross section in FIG. 3A. The XZ cross section including the e-e’ cross section is an XZ plane passing through the first emitter formation region 61 in the transistor portion 70. The trench contact portion 58 may have the plug portion 59 and/or the barrier metal 53. The semiconductor device 100 in the present example includes a plug region 13 below the trench contact portion 58. The cathode region 82 in the present example has a first cathode portion 182 and a second cathode portion 282. In the present example, points different from the semiconductor device 100 in FIG. 2B will be particularly described. Other points may be the same as those of the semiconductor device 100 in FIG. 2B.

The plug region 13 is a region provided above the drift region 18 and having a doping concentration higher than that of the base region 14. The plug region 13 in the present example is provided below the trench contact portion 58. The plug region 13 in the present example is in contact with a bottom surface of the trench contact portion 58. The plug region 13 may be in contact with a sidewall of the trench contact portion 58. The plug region 13 is region of the second conductivity type, having a doping concentration higher than that of the base region 14. The plug region 13 in the present example has a doping concentration higher than that of the contact region 15. A doping concentration of a dopant of the second conductivity type in the plug region 13 may be less than or equal to a doping concentration of a dopant of the first conductivity type in the first emitter region 121.

The plug region 13 may be provided so as to extend in the trench extending direction at the bottom surface of the trench contact portion 58. The plug region 13 may be provided over an entirety of the bottom surface of the trench contact portion 58. Plug regions 13 may also be provided in the boundary region 90 and the diode portion 80.

A lower end of the trench contact portion 58 may be deeper than a lower end of the emitter region 12. The lower end of the trench contact portion 58 in the present example is deeper than the lower end of the first emitter region 121. The lower end of the trench contact portion 58 may be shallower than the lower end of the base region 14. The sidewall of the trench contact portion 58 may be in contact with the first emitter region 121 and the plug region 13.

The first cathode portion 182 and the second cathode portion 282 are provided on the back surface 23 side of the semiconductor substrate 10 with respect to the drift region 18. The first cathode portion 182 is a region of the first conductivity type, having a doping concentration higher than that of the drift region 18. The second cathode portion 282 is a region of the second conductivity type, provided in contact with the first cathode portion 182. The first cathode portion 182 and the second cathode portion 282 may be repeatedly provided in a predetermined direction. The first cathode portion 182 and the second cathode portion 282 may be repeatedly provided in the trench array direction, or may be repeatedly provided in the trench extending direction. Changing a ratio between the first cathode portion 182 and the second cathode portion 282 can adjust characteristics such as the forward voltage of the diode portion 80. An area of the first cathode portion 182 at the back surface 23 of the semiconductor substrate 10 may be larger than an area of the second cathode portion 282 at the back surface 23 of the semiconductor substrate 10.

FIG. 3C illustrates an example of an XZ cross section including an f-f’ cross section in FIG. 3A. The XZ cross section including the f-f’ cross section is an XZ plane passing through the second emitter formation region 62 in the transistor portion 70. In the present example, points different from the e-e’ cross section in FIG. 3B will be particularly described. Other points may be the same as those of the e-e’ cross section in FIG. 3B.

The lower end of the trench contact portion 58 may be deeper than the lower end of the second emitter region 122. The lower end of the trench contact portion 58 may be shallower than the lower end of the trench sidewall region 11. It should be noted, however, that the lower end of the trench contact portion 58 may be deeper than the lower end of the trench sidewall region 11. The sidewall of the trench contact portion 58 may be in contact with the second emitter region 122 and the plug region 13.

The trench contact portion 58 is spaced apart from the trench sidewall region 11. The plug region 13 and the base region 14 may be provided between the trench contact portion 58 and the trench sidewall region 11. It should be noted, however, that the trench contact portion 58 may be in contact with the trench sidewall region 11.

The plug region 13 is spaced apart from the trench sidewall region 11. The base region 14 may be provided between the plug region 13 and the trench sidewall region 11. It should be noted, however, that the plug region 13 may be in contact with the trench sidewall region 11.

The semiconductor device 100 in the present example can suppress an influence of the trench contact portion 58 on a gate threshold voltage. This allows the gate threshold voltage to be controlled independently of the trench contact portion 58.

FIG. 3D illustrates an example of an XZ cross section including a g-g’ cross section in FIG. 3A. The XZ cross section including the g-g’ cross section is an XZ plane passing through the contact formation region 63 in the transistor portion 70. In the present example, points different from the e-e’ cross section in FIG. 3B will be particularly described. Other points may be the same as those of the e-e’ cross section in FIG. 3B.

The lower end of the trench contact portion 58 is shallower than a lower end of the contact region 15. It should be noted, however, that the lower end of the trench contact portion 58 may be deeper than the lower end of the contact region 15. The sidewall of the trench contact portion 58 may be in contact with the contact region 15 and the plug region 13.

A lower end of the plug region 13 is deeper than the lower end of the contact region 15. It should be noted, however, that the lower end of the plug region 13 may be shallower than the lower end of the contact region 15.

FIG. 3E shows an example of a YZ cross section including a h-h’ cross section in FIG. 3A. The YZ cross section including the h-h’ cross section is a YZ plane passing through the mesa portion 71 of the transistor portion 70. The h-h’ cross section is a cross section that does not pass through the contact hole 54. In the present figure, the lower end of the trench contact portion 58 is indicated by a broken line. Even when the semiconductor device 100 includes the trench contact portion 58, the first emitter formation region 61, the second emitter formation region 62, and the contact formation region 63 may be repeatedly arranged similarly to a case shown in FIG. 2E in which the semiconductor device 100 does not include the trench contact portion 58.

In the present specification, what has been described in an embodiment in which the trench contact portion 58 is provided, may also be appropriately applied to the semiconductor device 100 not including the trench contact portion 58. Similarly, what has been described in an embodiment in which the trench contact portion 58 is not provided, may also be appropriately applied to the semiconductor device 100 including the trench contact portion 58.

FIG. 3F shows an example of a YZ cross section including an i-i’ cross section in FIG. 3A. The YZ cross section including the i-i’ cross section is a YZ plane passing through the mesa portion 81 of the diode portion 80. The i-i’ cross section is a cross section that does not pass through the contact hole 54.

Plug regions 13 may be discretely provided at the lower end of the trench contact portion 58 in the trench extending direction, or the plug region 13 may not be provided. The plug region 13 may be continuously provided at the lower end of the trench contact portion 58 in the trench extending direction. In the present example, the plug regions 13 are discretely provided at the lower end of the trench contact portion 58 in the trench extending direction. It should be noted, however, that the plug region 13 may be continuously provided so as to extend in the trench extending direction at the lower end of the trench contact portion 58. A region in which the plug regions 13 are provided may be appropriately changed in consideration of characteristics such as the forward voltage of the diode portion 80.

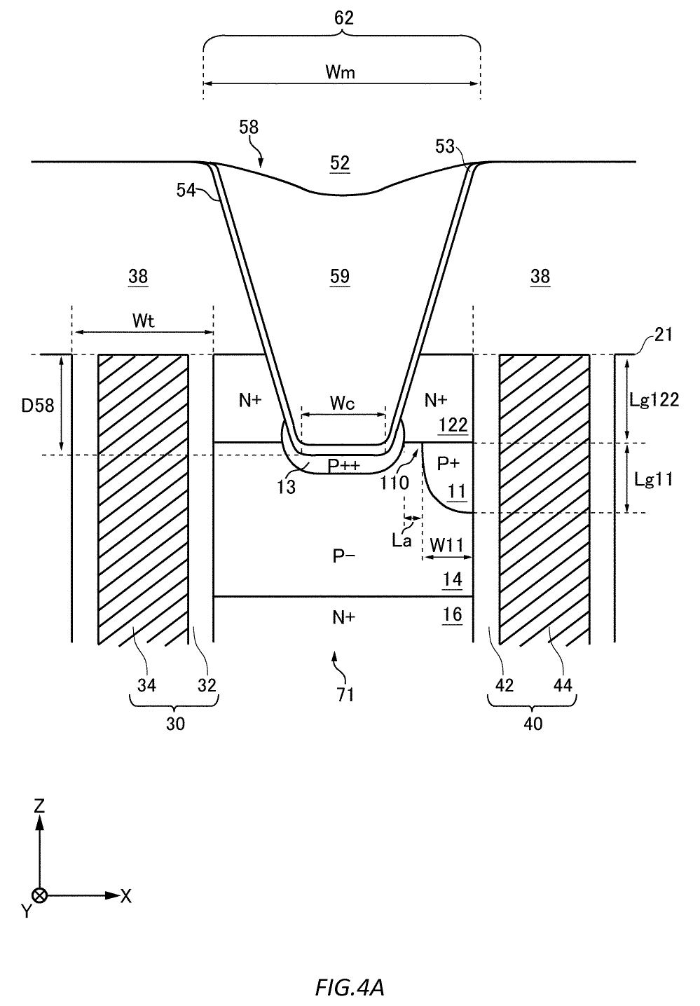

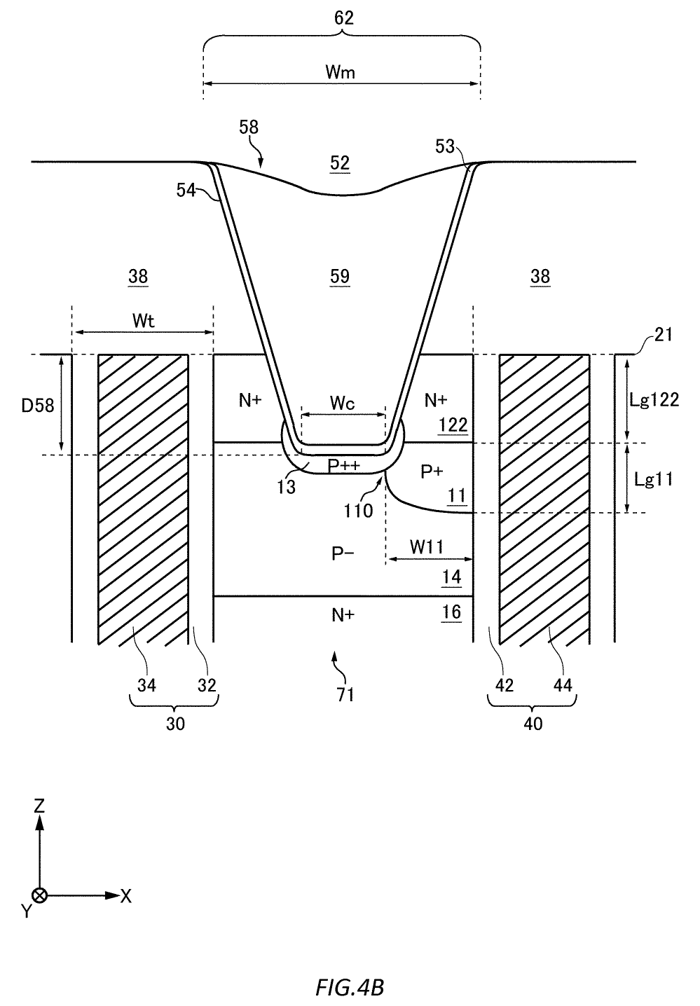

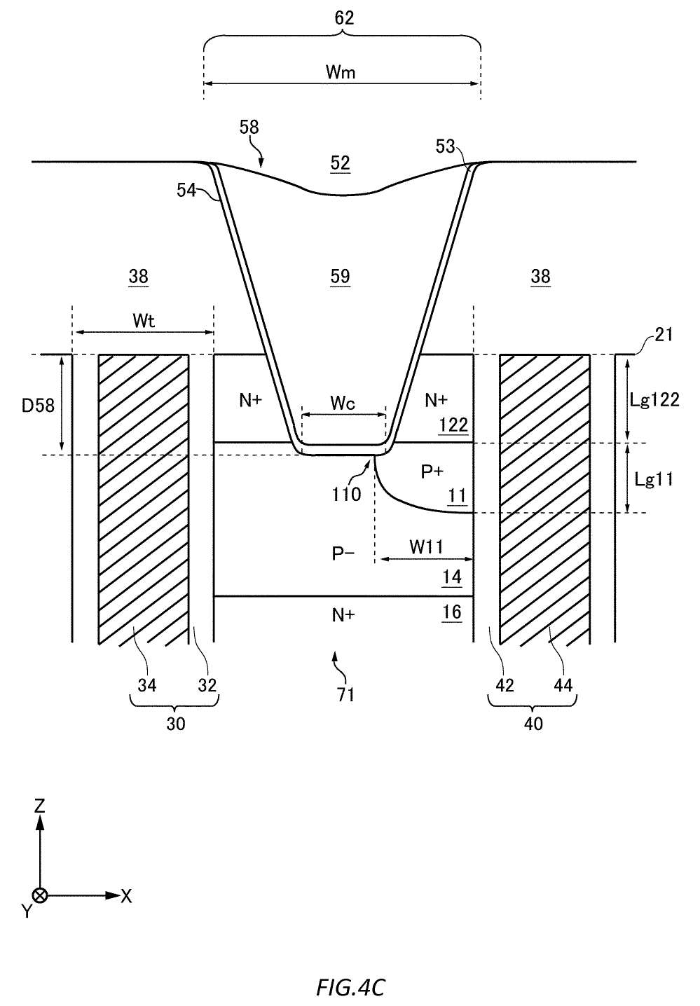

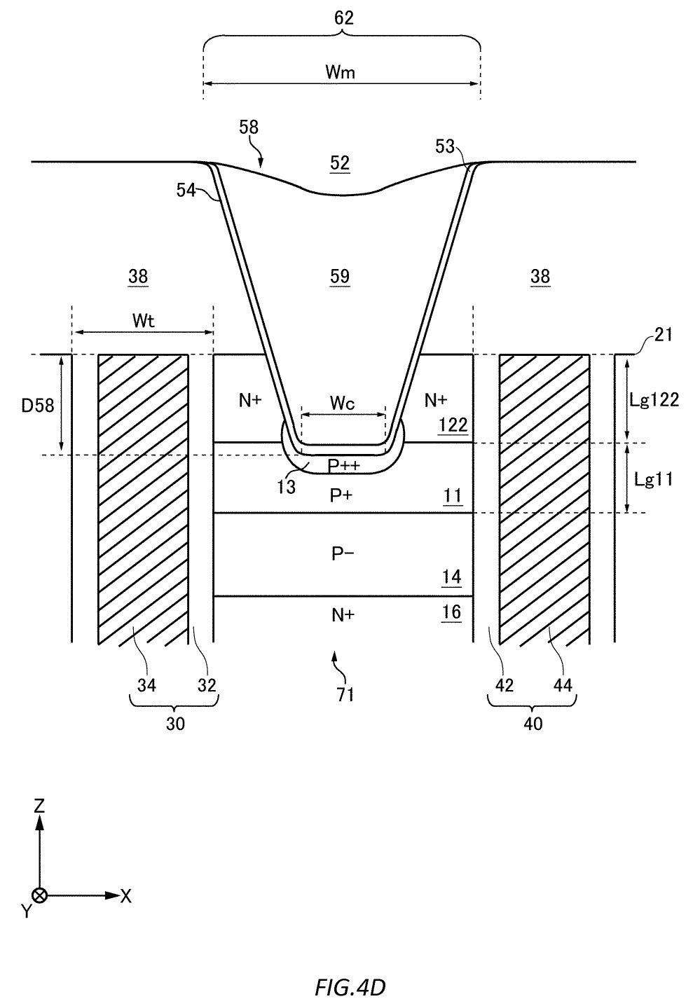

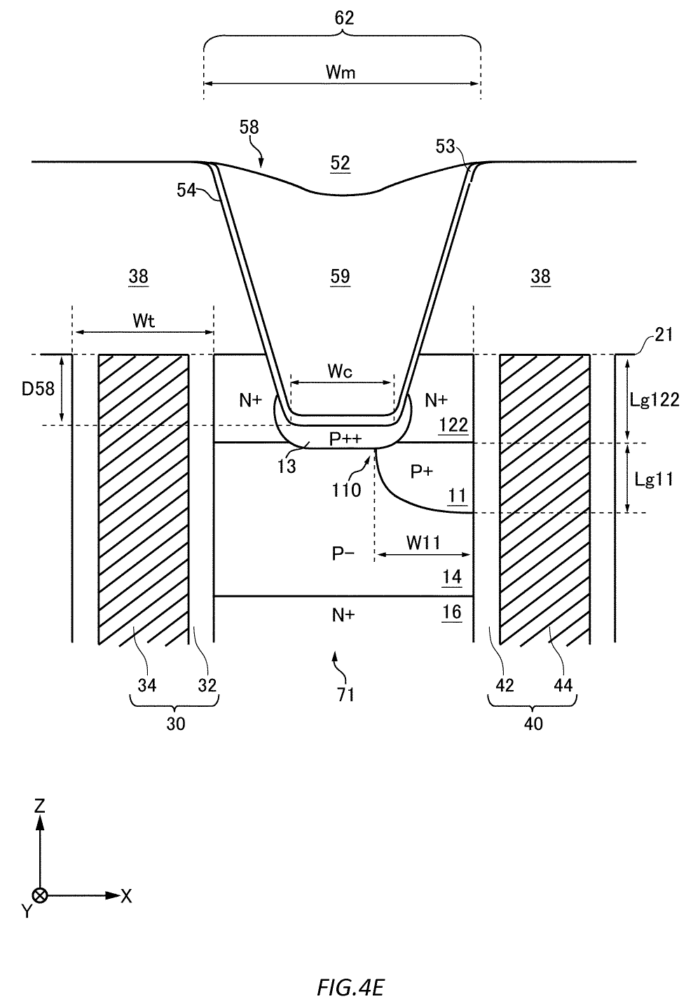

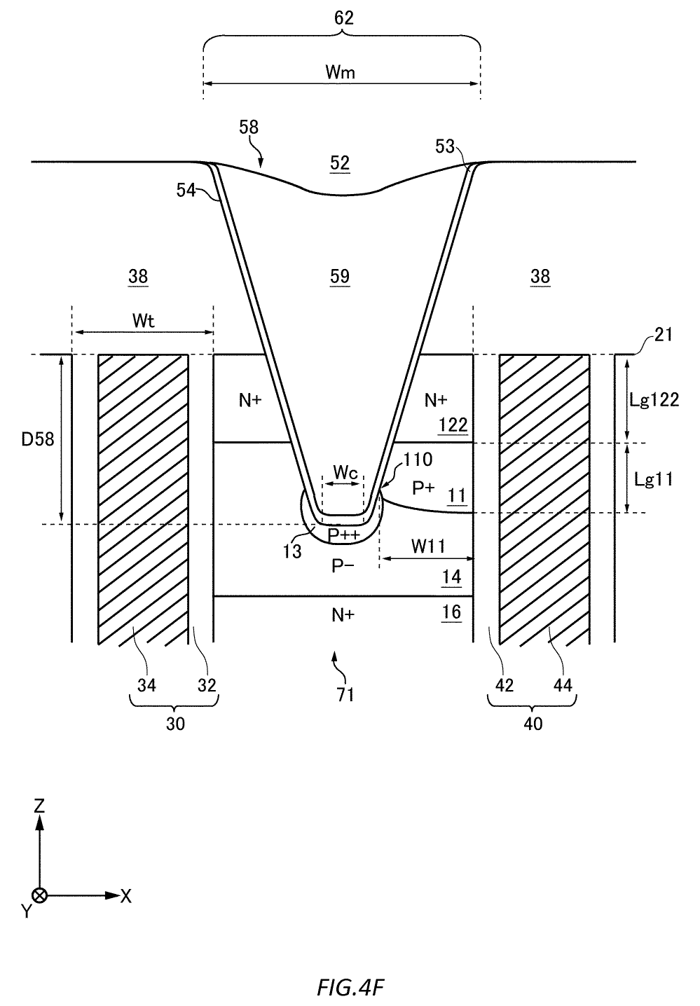

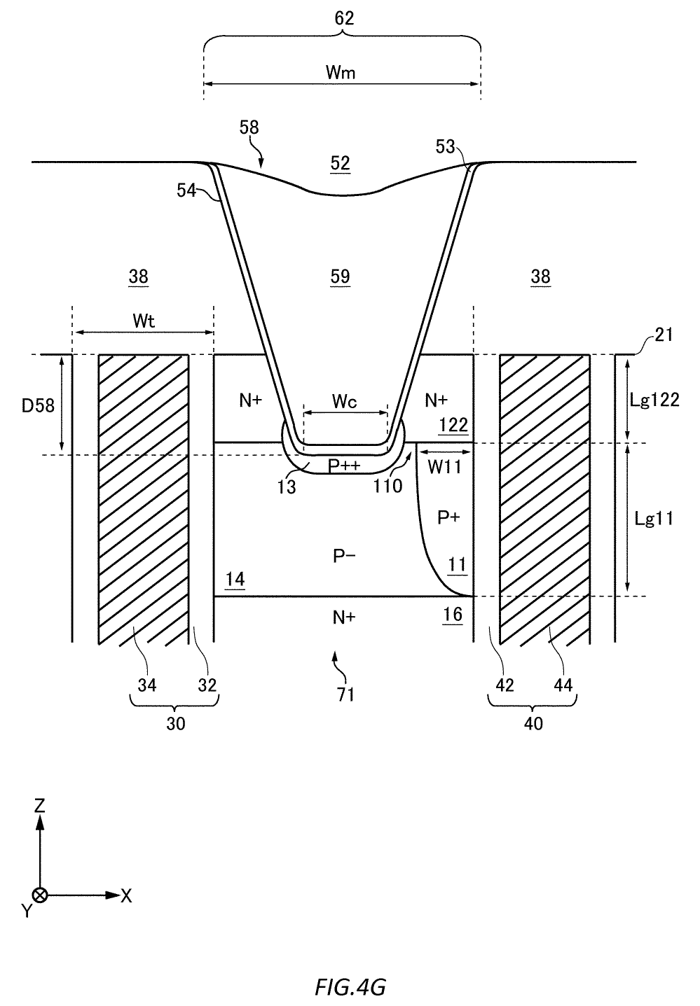

FIG. 4A is an enlarged view of a modification example of an XZ cross section passing through the second emitter formation region 62. The present figure shows the mesa portion 71 sandwiched between the dummy trench portion 30 and the gate trench portion 40.

The plug region 13 may be in contact with the sidewall of the trench contact portion 58 on the dummy trench portion 30 side, and may be in contact with the sidewall of the trench contact portion 58 on the gate trench portion 40 side. The plug region 13 in the present example is in contact with both the sidewall on the dummy trench portion 30 side and the sidewall on the gate trench portion 40 side of the trench contact portion 58. The sidewall of the trench contact portion 58 in the present example is in contact with the second emitter region 122 and the plug region 13.

The length Lg122 is a length of the second emitter region 122 that is in contact with the sidewall of the gate trench portion 40. The length Lg122 may be a length in the depth direction of the semiconductor substrate 10. The length Lg122 may be the same as the thickness D122 of the second emitter region 122.

A length Lg11 is a length of contact between the trench sidewall region 11 and the gate trench portion 40 below the second emitter region 122. The length Lg11 may be determined such that a channel is not formed at the sidewall of the gate trench portion 40. The length Lg11 may be determined in consideration of an amount of holes to be implanted from the transistor portion 70 into the diode portion 80. For example, the length Lg11 is 0.1 μm or more and 3.0 μm or less.

A depth D58 indicates a distance from the front surface 21 to the lower end of the trench contact portion 58 in the depth direction of the semiconductor substrate 10. Increasing the depth D58 makes it easier to suppress the amount of hole injection from the transistor portion 70 into the diode portion 80 and reduce the reverse recovery loss Err. The depth D58 in the present example is deeper than the lower end of the second emitter region 122. Therefore, the depth D58 is greater than the length Lg11.

An end portion 110 indicates an end portion of the trench sidewall region 11 that is farthest away from the sidewall of the gate trench portion 40 in the trench array direction. The end portion 110 in the present example is located between the trench contact portion 58 and the gate trench portion 40 in the trench array direction. That is, the trench sidewall region 11 extends from the sidewall of the gate trench portion 40 in the trench array direction and terminates without being in contact with the trench contact portion 58.

The trench sidewall region 11 in the present example is spaced apart from the plug region 13. A distance La between the trench sidewall region 11 and the plug region 13 may be 0.05 μm or more and 0.2 μm or less.

A width W11 is a width of the trench sidewall region 11 in the trench array direction. The width W11 is a width from the sidewall of the gate trench portion 40 with which the trench sidewall region 11 is in contact, to the end portion 110 of the trench sidewall region 11. The width W11 may be 0.05 μm or more, and less than or equal to a mesa width Wm of the mesa portion 71. The width W11 in the present example is smaller than half of the mesa width Wm of the mesa portion 71, but may be greater than half of the mesa width Wm of the mesa portion 71. The mesa width Wm may be 0.5 μm or more and 1.3 μm or less. The width W11 may be less than or equal to a trench width Wt. The trench width Wt is not particularly limited, but may be 0.8 μm or more and 1.4 μm or less. The width W11 may be less than or equal to a contact width Wc at the bottom surface of the contact hole 54. The contact width Wc may be 0.1 μm or more and 0.3 μm or less. The semiconductor device 100 can prevent formation of a channel by making the width W11 greater than a thickness of an inversion layer formed at the sidewall of the gate trench portion 40.

FIG. 4B is an enlarged view of a modification example of an XZ cross section passing through the second emitter formation region 62. The second emitter formation region 62 in the present example is different from the second emitter formation region 62 in FIG. 4A in that the trench sidewall region 11 is in contact with the plug region 13. In the present example, points different from the second emitter formation region 62 in FIG. 4A will be particularly described. Other points may be the same as those of the second emitter formation region 62 in FIG. 4A.

The plug region 13 is provided at the lower end of the trench contact portion 58 and may be in contact with the trench sidewall region 11. A sidewall of the plug region 13 may be in contact with the trench sidewall region 11, or the lower end of the plug region 13 may be in contact with the trench sidewall region 11. As a result of the plug region 13 being in contact with the trench sidewall region 11, a gate threshold voltage of the gate trench portion 40 increases. The semiconductor device 100 in the present example can increase the gate threshold voltage while suppressing latch-up.

FIG. 4C is an enlarged view of a modification example of an XZ cross section passing through the second emitter formation region 62. The second emitter formation region 62 in the present example is different from the second emitter formation region 62 in FIG. 4B in that it does not have the plug region 13. Other points may be the same as those of the second emitter formation region 62 in FIG. 4B.

When the plug region 13 is not provided in the second emitter formation region 62, the plug region 13 may also not be provided in another region of the semiconductor device 100. Not providing the plug region 13 makes it easier to suppress the hole injection from the transistor portion 70 into the diode portion 80. The trench contact portion 58 in the present example is in contact with the trench sidewall region 11, but may be spaced apart from the trench sidewall region 11.

FIG. 4D is an enlarged view of a modification example of an XZ cross section passing through the second emitter formation region 62. The second emitter formation region 62 in the present example is different from the second emitter formation region 62 in FIG. 4B, in a region in which the trench sidewall region 11 is formed. Other points may be the same as those of the second emitter formation region 62 in FIG. 4B.

The trench sidewall region 11 extends from one trench portion that is in direct contact with the mesa portion 71 to another trench portion. That is, the width W11 of the trench sidewall region 11 is equal to the mesa width Wm of the mesa portion 71. The trench sidewall region 11 in the present example extends from the sidewall of the gate trench portion 40 to a sidewall of the dummy trench portion 30. Providing the trench sidewall region 11 so as to extend from one trench portion to another trench portion in the trench array direction can avoid an influence of mask misalignment for forming the trench sidewall region 11. The semiconductor device 100 in the present example can reduce latch-up by increasing a region for forming the trench sidewall region 11 while suppressing the influence of mask misalignment of the trench sidewall region 11.

FIG. 4E is an enlarged view of a modification example of an XZ cross section passing through the second emitter formation region 62. The second emitter formation region 62 in the present example is different from the second emitter formation region 62 in FIG. 4B in that a depth of the trench contact portion 58 is shallower than the second emitter region 122. Other points may be the same as those of the second emitter formation region 62 in FIG. 4B.

The lower end of the trench contact portion 58 is shallower than the lower end of the second emitter region 122. That is, the depth D58 is smaller than a length Lg122. The lower end of the plug region 13 may be deeper than the lower end of the second emitter region 122.

The sidewall of the trench contact portion 58 is in contact with the second emitter region 122 and the plug region 13. The trench contact portion 58 may be spaced apart from the trench sidewall region 11. The plug region 13 in the present example is in contact with the trench sidewall region 11, but may be spaced apart from the trench sidewall region 11. The plug region 13 may be omitted.

FIG. 4F is an enlarged view of a modification example of an XZ cross section passing through the second emitter formation region 62. The second emitter formation region 62 in the present example is different from the second emitter formation region 62 in FIG. 4B in that the depth of the trench contact portion 58 is deeper than the trench sidewall region 11. Other points may be the same as those of the second emitter formation region 62 in FIG. 4B.

The lower end of the trench contact portion 58 is deeper than the lower end of the trench sidewall region 11. That is, the depth D58 is greater than a sum of the length Lg122 and the length Lg11. The lower end of the trench contact portion 58 may be shallower than the lower end of the base region 14. The lower end of the plug region 13 is deeper than the lower end of the trench sidewall region 11. The lower end of the plug region 13 may be shallower than the lower end of the base region 14.

The sidewall of the trench contact portion 58 is in contact with the second emitter region 122, the trench sidewall region 11, and the plug region 13. The trench contact portion 58 may be spaced apart from the trench sidewall region 11. In this case, the sidewall of the trench contact portion 58 may be in contact with the second emitter region 122, the base region 14, and the plug region 13. The plug region 13 in the present example is in contact with the trench sidewall region 11, but may be spaced apart from the trench sidewall region 11. The plug region 13 may be omitted.

FIG. 4G is an enlarged view of a modification example of an XZ cross section passing through the second emitter formation region 62. The second emitter formation region 62 in the present example is different from the second emitter formation region 62 in FIG. 4A in a depth of the trench sidewall region 11. Other points may be the same as those of the second emitter formation region 62 in FIG. 4A.

The lower end of the trench sidewall region 11 is in contact with an upper end of the accumulation region 16. The lower end of the trench sidewall region 11 may be at the same position as that of the lower end of the base region 14 in the depth direction of the semiconductor substrate 10. The trench sidewall region 11 in the present example is spaced apart from the trench contact portion 58 and the plug region 13, but may be in contact with at least one of the trench contact portion 58 or the plug region 13. Increasing the length Lg11 of the trench sidewall region 11 can flatten electric field distribution in the mesa portion 71, reduce the electric field strength, and improve reliability of the semiconductor device 100. The trench sidewall region 11 may extend, in the array direction, from the sidewall of the gate trench portion 40 to the sidewall of the dummy trench portion 30.

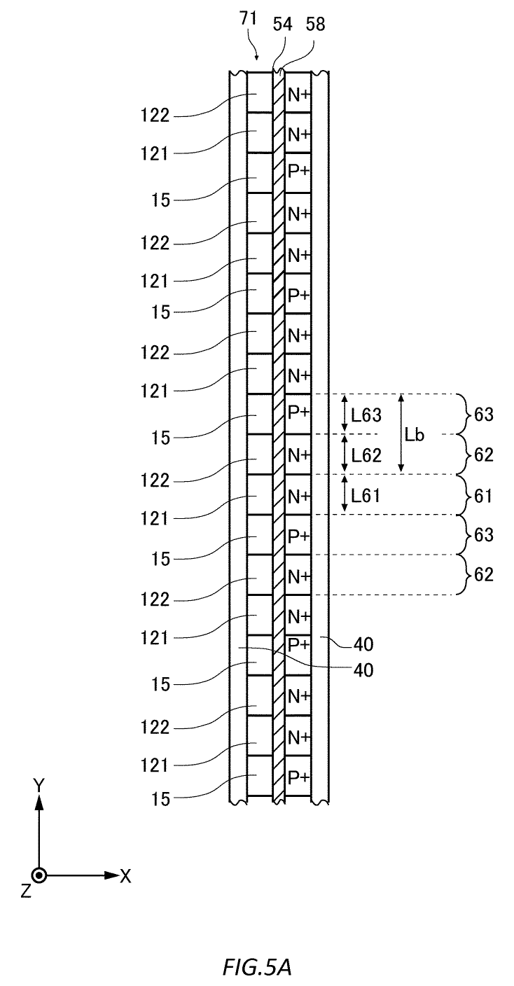

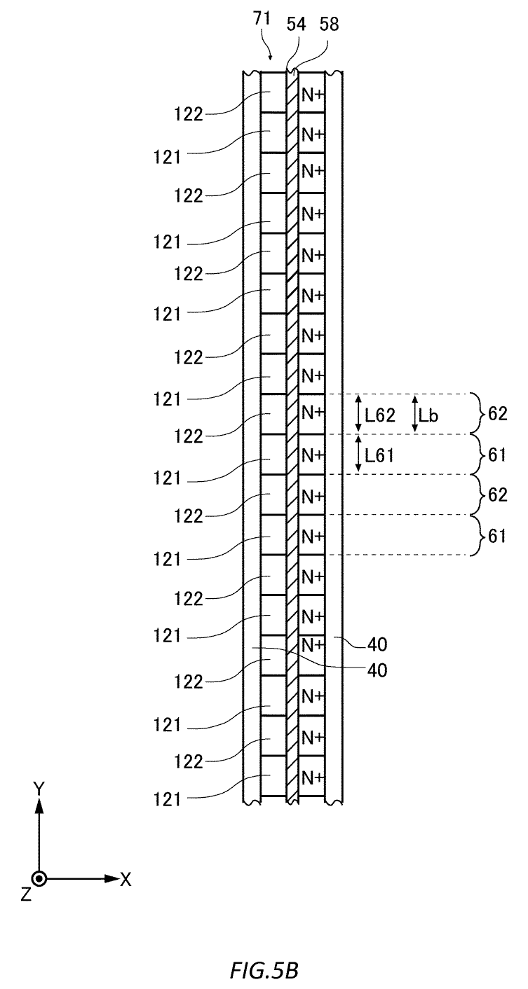

FIG. 5A is an enlarged top view of a modification example of the semiconductor device 100. In the present example, arrangement of the first emitter formation region 61, the second emitter formation region 62, and the contact formation region 63 is different from arrangement of the semiconductor device 100 in FIG. 2A. In the present example, points different from the semiconductor device 100 in FIG. 2A will be particularly described. Other points may be the same as those of the semiconductor device 100 in FIG. 2A.

The first emitter formation region 61 is in contact with the second emitter formation region 62 and the contact formation region 63. In the trench extending direction, one end of the first emitter formation region 61 is in contact with the second emitter formation region 62, and another end of the first emitter formation region 61 is in contact with the contact formation region 63.

The second emitter formation region 62 is in contact with the first emitter formation region 61 and the contact formation region 63. In the trench extending direction, one end of the second emitter formation region 62 is in contact with the first emitter formation region 61, and another end of the second emitter formation region 62 is in contact with the contact formation region 63.

The contact formation region 63 is in contact with the first emitter formation region 61 and the second emitter formation region 62. In the trench extending direction, one end of the contact formation region 63 is in contact with the first emitter formation region 61, and another end of the contact formation region 63 is in contact with the second emitter formation region 62.

The first emitter formation region 61, the second emitter formation region 62, and the contact formation region 63 are repeatedly provided in this order in the trench extending direction.

The length Lb is a length, in the trench extending direction, of a region consisting of the second emitter formation region 62 and the contact formation region 63. That is, the length Lb is a sum of the length L62 and the length L63.

In the present example, the mesa portion 71 sandwiched between two gate trench portions 40 is described as an example, but a structure in the present example may be applied to the mesa portion 71 sandwiched between the dummy trench portion 30 and the gate trench portion 40 that are adjacent to each other.

FIG. 5B is an enlarged top view of a modification example of the semiconductor device 100. The mesa portion 71 in the present example is different from the mesa portion 71 in FIG. 2A in that it does not have the contact formation region 63. In the present example, points different from the semiconductor device 100 in FIG. 2A will be particularly described. Other points may be the same as those of the semiconductor device 100 in FIG. 2A.

The first emitter formation region 61 and the second emitter formation region 62 are alternately and repeatedly provided in the trench extending direction. The first emitter formation region 61 in the present example is in contact with the second emitter formation region 62. In the trench extending direction, both ends of the first emitter formation region 61 are in contact with second emitter formation regions 62. Similarly, in the trench extending direction, both ends of the second emitter formation region 62 are in contact with first emitter formation regions 61.

The length Lb is a length of the second emitter formation region 62 in the trench extending direction. That is, the length Lb is equal to the length L62. The semiconductor device 100 in the present example can further reduce the amount of hole injection into the diode portion 80 by omitting the contact formation region 63.

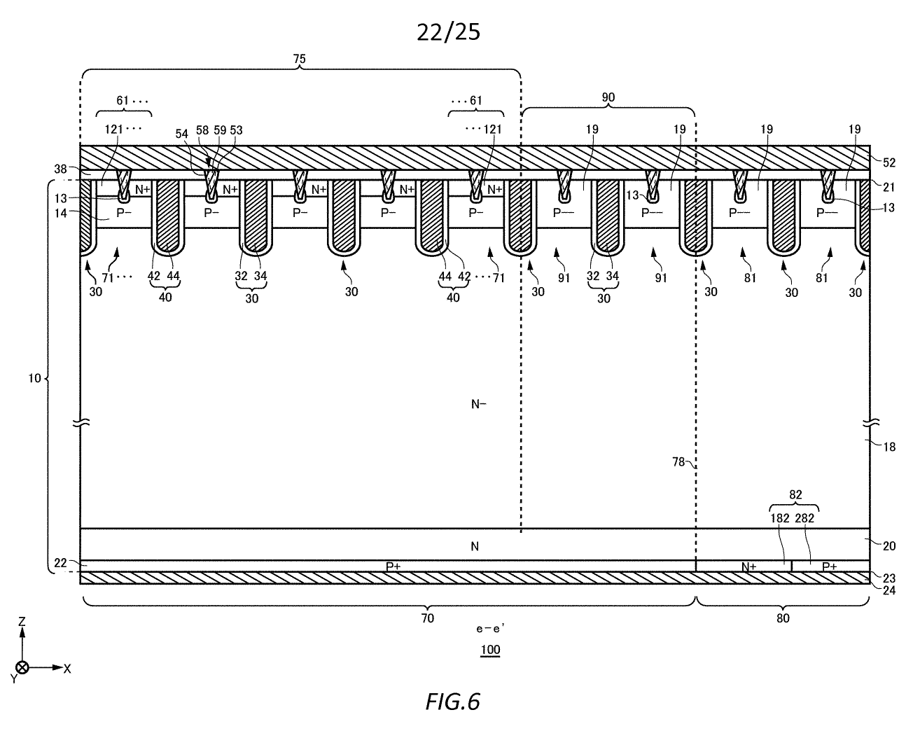

FIG. 6 illustrates a modification example of an XZ cross section including the e-e’ cross section in FIG. 3A. The e-e’ cross-sectional view in the present example is different from the e-e’ cross-sectional view in FIG. 3B in that it does not include the accumulation region 16. In the present example, points different from the e-e’ cross-sectional view in FIG. 3B will be particularly described. Other points may be the same as those of the e-e’ cross section in FIG. 3B.

The mesa portion 71 has the plug region 13, the base region 14, the drift region 18, and the first emitter region 121, but does not have the accumulation region 16. A bottom surface of the base region 14 in the present example is in contact with an upper surface of the drift region 18.

At the sidewall of the gate trench portion 40 of the first emitter formation region 61, the base region 14 may be in contact with the first emitter region 121. At the sidewall of the gate trench portion 40 of the first emitter formation region 61, the drift region 18 may be in contact with the base region 14. That is, at the sidewall of the gate trench portion 40 of the first emitter formation region 61, the trench sidewall region 11 may not be provided below the first emitter region 121.

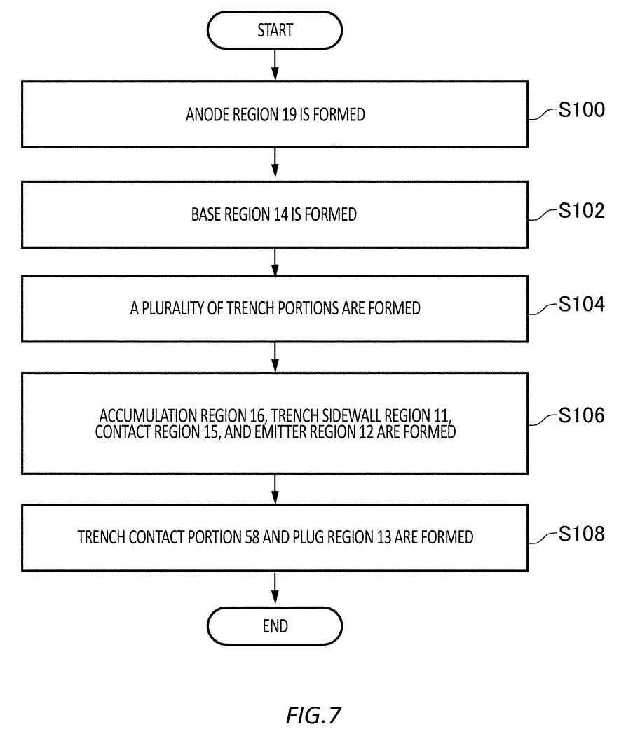

FIG. 7 shows an example of a method for manufacturing the semiconductor device 100. In the present example, an example of a method for manufacturing the semiconductor device 100 is shown, and an order of respective steps or the like may be appropriately changed.

In step S100, the anode region 19 is formed above the drift region 18. In step S102, the base region 14 is formed above the drift region 18. When the base region 14 and the anode region 19 have the same doping concentration, the base region 14 and the anode region 19 may be simultaneously formed in a common process.

In step S104, a plurality of trench portions are formed at the front surface 21 of the semiconductor substrate 10. The dummy trench portion 30 and the gate trench portion 40 may be simultaneously formed in a common process, or the dummy trench portion 30 and the gate trench portion 40 may be separately formed. Step S104 may be performed prior to step S100 and step S102.

In step S106, the accumulation region 16, the trench sidewall region 11, the contact region 15, and the emitter region 12 are formed. An order in which the accumulation region 16, the trench sidewall region 11, the contact region 15, and the emitter region 12 are formed is not limited. In step S106, the respective regions may be formed in descending order of distance from the front surface 21 in the depth direction of the semiconductor substrate 10. In an example, the accumulation region 16, the trench sidewall region 11, the contact region 15, and the emitter region 12 are formed in this order. Annealing for activation may be collectively performed after ion implantations for forming the respective regions are performed, or may be individually performed after each ion implantation is performed.

In the present example, the first emitter region 121 and the second emitter region 122 are formed as the emitter region 12. The first emitter region 121 and the second emitter region 122 may be simultaneously formed in an ion implantation process under the same condition, or may be separately formed.

A dopant of the emitter region 12 may be ion-implanted after a dopant of the accumulation region 16 is ion-implanted, or may be ion-implanted before a dopant of the accumulation region 16 is ion-implanted. The dopant of the emitter region 12 may be ion-implanted after a dopant of the contact region 15 is ion-implanted, or may be ion-implanted before a dopant of the contact region 15 is ion-implanted. The dopant of the emitter region 12 may be ion-implanted after a dopant of the trench sidewall region 11 is ion-implanted, or may be ion-implanted before a dopant of the trench sidewall region 11 is ion-implanted.

The dopant of the trench sidewall region 11 may be ion-implanted after the dopant of the contact region 15 is ion-implanted, or may be ion-implanted before the dopant of the contact region 15 is ion-implanted. The dopant of the trench sidewall region 11 may be ion-implanted after the dopant of the accumulation region 16 is ion-implanted, or may be ion-implanted before the dopant of the accumulation region 16 is ion-implanted.

In step S108, the trench contact portion 58 and the plug region 13 are formed. The plug region 13 may be formed by forming the contact hole 54 of the trench contact portion 58 and thereafter ion-implanting a dopant of the second conductivity type into a lower end of the contact hole 54. After the plug region 13 is formed, the trench contact portion 58 may be formed by filling the contact hole 54 with the barrier metal 53 and the plug portion 59.

The trench contact portion 58 in the present example is formed after the emitter region 12 is formed, but may be formed before the emitter region 12 is formed.

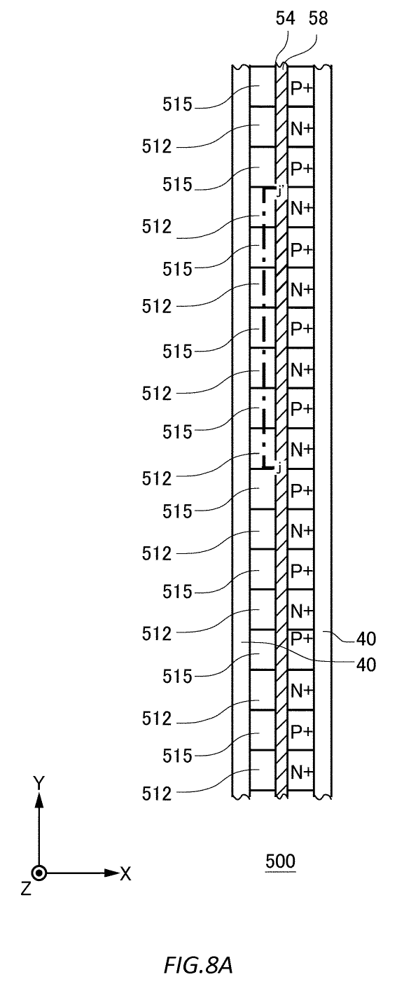

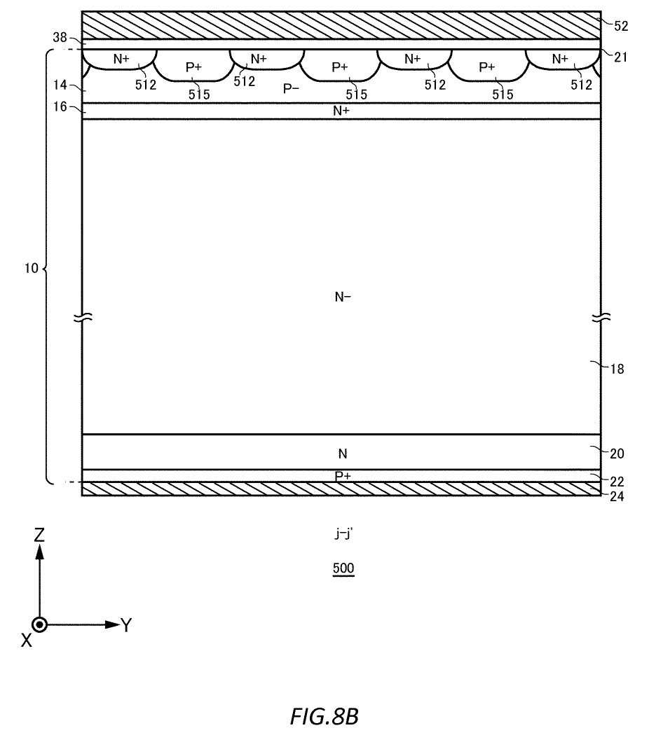

FIG. 8A is a top view of a semiconductor device 500 of a comparative example. The semiconductor device 500 includes an emitter region 512 and a contact region 515. The emitter region 512 and the contact region 515 are alternately provided in the trench extending direction. The emitter region 512 extends, in the trench array direction, from one of two adjacent gate trench portions 40 to another of the two adjacent gate trench portions 40. The contact region 515 extends, in the trench array direction, from one of two adjacent gate trench portions 40 to another of the two adjacent gate trench portions 40.

FIG. 8B shows a YZ cross section including a j-j’ cross section in FIG. 8A. The YZ cross section including the j-j’ cross section is a YZ plane passing through a mesa portion of the semiconductor device 500. The trench sidewall region 11 is not provided below the emitter region 512. Therefore, a region in which the emitter region 512 is formed functions as a channel region, and the contact region 515 is provided in a region that does not function as a channel region. Changing a width of the contact region 515 in the trench extending direction, with a width of the emitter region 512 in the trench extending direction fixed, to adjust a saturation current causes a trade-off relationship to arise between the latch-up tolerance and the amount of hole injection into the diode portion. For example, increasing the width of the contact region 515 in the trench extending direction to adjust the saturation current may improve the latch-up tolerance, but increase the amount of hole injection into the diode portion. On the other hand, decreasing the width of the contact region 515 in the trench extending direction to adjust the saturation current may decrease the amount of hole injection into the diode portion, but decrease the latch-up tolerance.

In contrast, the semiconductor device 100 has, as regions that do not function as channels, the second emitter formation region 62 and the contact formation region 63 of the second conductivity type, having different concentrations. This allows the amount of hole injection to be controlled independently of the channel density. That is, even when the first emitter formation region 61 functioning as a channel region is fixed, the semiconductor device 100 can adjust the latch-up tolerance and the amount of hole injection into the diode portion by adjusting a ratio between the second emitter formation region 62 and the contact formation region 63. Therefore, the semiconductor device 100 can improve the latch-up tolerance and reduce the reverse recovery loss Err while realizing a desired saturation current.

As described above, the present invention has been described using embodiments, but the technical scope of the present invention is not limited to the scope described in the above-described embodiments. It is apparent to those skilled in the art that various changes or improvements can be made to the above-described embodiments. It is apparent from the description of the claims that embodiments to which such changes or improvements are made may also be included in the technical scope of the present invention.

It should be noted that an execution order of respective processings such as operations, procedures, steps, and stages in a device, a system, a program, and a method shown in the claims, the specification, and the drawings can be realized in any order unless "before", "prior to", and the like are explicitly stated in particular, and unless an output of a previous processing is used in a subsequent processing. Even if, for convenience, an operation flow in the claims, the specification, and the drawings is described using "first", "next", and the like, this does not mean that performing in this order is essential.

### (Item 1)

A semiconductor device comprising a transistor portion and a diode portion, the semiconductor device comprising: a drift region of a first conductivity type, provided in the semiconductor substrate; a plurality of trench portions extending in a predetermined trench extending direction on a front surface side of the semiconductor substrate; a base region of a second conductivity type, provided above the drift region; a first emitter region of the first conductivity type, provided at a front surface of the semiconductor substrate and having a doping concentration higher than that of the drift region; a second emitter region of the first conductivity type, provided at the front surface of the semiconductor substrate and having a doping concentration higher than that of the drift region; and a trench sidewall region of the second conductivity type, provided above the drift region and having a doping concentration higher than that of the base region; wherein each of the plurality of trench portions has a gate trench portion, and wherein any of first mesa portions between the plurality of trench portions includes: a first emitter formation region in which the first emitter region is provided at a sidewall of the gate trench portion; and a second emitter formation region in which the trench sidewall region is provided at the sidewall of the gate trench portion below the second emitter region.

### (Item 2)

The semiconductor device according to item 1, comprising a contact region of the second conductivity type, provided above the drift region and having a doping concentration higher than that of the base region, wherein the first mesa portion includes a contact formation region in which the contact region is provided at the front surface.

### (Item 3)

The semiconductor device according to item 2, wherein a length of the first emitter formation region in the trench extending direction is greater than a length of the contact formation region in the trench extending direction.

### (Item 4)

The semiconductor device according to item 2, wherein, in the trench extending direction, both ends of the first emitter formation region are in contact with contact formation regions, each being the contact formation region.

### (Item 5)

The semiconductor device according to item 2, wherein, in the trench extending direction, one end of the contact formation region is in contact with the first emitter formation region, and another end of the contact formation region is in contact with the second emitter formation region.

### (Item 6)

The semiconductor device according to item 2, wherein, in the trench extending direction, both ends of the second emitter formation region are in contact with contact formation regions, each being the contact formation region.

### (Item 7)

The semiconductor device according to item 6, wherein a length Lb, in the trench extending direction, of a region consisting of the second emitter formation region and the contact formation regions provided at both ends of the second emitter formation region, is greater than or equal to a length of the first emitter formation region in the trench extending direction.

### (Item 8)

The semiconductor device according to item 2, wherein, in the trench extending direction, the first emitter formation region, the contact formation region, the second emitter formation region, and the contact formation region are repeatedly provided in this order.

### (Item 9)

The semiconductor device according to item 1, wherein the first emitter region extends, in a trench array direction, from one trench portion that is in contact with the first mesa portion to another trench portion that faces the one trench portion.

### (Item 10)

The semiconductor device according to item 1, wherein a doping concentration of the first emitter region is the same as a doping concentration of the second emitter region.

### (Item 11)

The semiconductor device according to item 1, wherein the trench sidewall region is in contact with a lower end of the second emitter region.

### (Item 12)

The semiconductor device according to item 2, wherein a doping concentration of the trench sidewall region is lower than a doping concentration of the contact region.

### (Item 13)

The semiconductor device according to item 1, wherein a doping concentration of the trench sidewall region is 1E17 cm⁻³ or more and 1E20 cm⁻³ or less.

### (Item 14)

The semiconductor device according to item 1, wherein a length of contact between the trench sidewall region and the sidewall of the gate trench portion below the second emitter region is 0.1 μm or more and 3.0 μm or less.

### (Item 15)

The semiconductor device according to item 1, wherein a width, in a trench array direction of the plurality of trench portions, of the trench sidewall region is 0.05 μm or more and is less than or equal to a mesa width of the first mesa portion.

### (Item 16)

The semiconductor device according to item 1, wherein the trench sidewall region extends from one trench portion that is in direct contact with the first mesa portion to another trench portion.

### (Item 17)

The semiconductor device according to item 1, comprising an accumulation region of the first conductivity type, provided above the drift region and having a doping concentration higher than that of the drift region.

### (Item 18)

The semiconductor device according to item 17, wherein a lower end of the trench sidewall region is in contact with an upper end of the accumulation region.

### (Item 19)

The semiconductor device according to any one of items 1 to 18, comprising a trench contact portion extending from the front surface of the semiconductor substrate in a depth direction of the semiconductor substrate.

### (Item 20)

The semiconductor device according to item 19, wherein the trench contact portion is spaced apart from the trench sidewall region.

### (Item 21)

The semiconductor device according to item 19, wherein a lower end of the trench contact portion is deeper than a lower end of the second emitter region and is shallower than a lower end of the trench sidewall region.

### (Item 22)

The semiconductor device according to item 19, comprising a plug region of the second conductivity type, provided above the drift region and having a doping concentration higher than that of the base region.

### (Item 23)

The semiconductor device according to item 22, wherein the plug region is spaced apart from the trench sidewall region.

### (Item 24)

The semiconductor device according to item 22, wherein the plug region is provided at a lower end of the trench contact portion and is in contact with the trench sidewall region.

### (Item 25)

The semiconductor device according to any one of items 1 to 18, comprising a cathode region provided on a back surface side of the semiconductor substrate with respective to the drift region, wherein the cathode region has: a second cathode portion of the second conductivity type, provided in contact with the first cathode portion.

a first cathode portion of the first conductivity type, having a doping concentration higher than that of the drift region; and

### (Item 26)

The semiconductor device according to any one of items 1 to 18, wherein the transistor portion has: a main region in which the first emitter formation region and the second emitter formation region are provided; and a boundary region provided adjacent to the diode portion rather than the main region.

### (Item 27)

The semiconductor device according to item 1, wherein, at the sidewall of the gate trench portion in the first emitter formation region, the base region is in contact with the first emitter region, and the drift region is in contact with the base region.

### (Item 28)

The semiconductor device according to item 17, wherein, at the sidewall of the gate trench portion in the first emitter formation region, the base region is in contact with the first emitter region, and the accumulation region is in contact with the base region.

What is claimed is:

1. A semiconductor device comprising a transistor portion and a diode portion, the semiconductor device comprising:
a drift region of a first conductivity type, provided in a semiconductor substrate;
a plurality of trench portions extending in a predetermined trench extending direction on a front surface side of the semiconductor substrate;
a base region of a second conductivity type, provided above the drift region;
a first emitter region of the first conductivity type, provided at a front surface of the semiconductor substrate and having a doping concentration higher than that of the drift region;
a second emitter region of the first conductivity type, provided at the front surface of the semiconductor substrate and having a doping concentration higher than that of the drift region; and
a trench sidewall region of the second conductivity type, provided above the drift region and having a doping concentration higher than that of the base region;
wherein each of the plurality of trench portions has a gate trench portion, and
wherein any of first mesa portions between the plurality of trench portions includes:
a first emitter formation region in which the first emitter region is provided at a sidewall of the gate trench portion; and
a second emitter formation region in which the trench sidewall region is provided at the sidewall of the gate trench portion below the second emitter region.

2. The semiconductor device according to claim 1, comprising a contact region of the second conductivity type, provided above the drift region and having a doping concentration higher than that of the base region,
wherein the first mesa portion includes a contact formation region in which the contact region is provided at the front surface.

3. The semiconductor device according to claim 2, wherein a length of the first emitter formation region in the trench extending direction is greater than a length of the contact formation region in the trench extending direction.

4. The semiconductor device according to claim 2, wherein, in the trench extending direction, both ends of the first emitter formation region are in contact with contact formation regions, each being the contact formation region.

5. The semiconductor device according to claim 2, wherein, in the trench extending direction, one end of the contact formation region is in contact with the first emitter formation region, and another end of the contact formation region is in contact with the second emitter formation region.

6. The semiconductor device according to claim 2, wherein, in the trench extending direction, both ends of the second emitter formation region are in contact with contact formation regions, each being the contact formation region.

7. The semiconductor device according to claim 6, wherein a length Lb, in the trench extending direction, of a region consisting of the second emitter formation region and the contact formation regions provided at both ends of the second emitter formation region, is greater than or equal to a length of the first emitter formation region in the trench extending direction.

8. The semiconductor device according to claim 2, wherein, in the trench extending direction, the first emitter formation region, the contact formation region, the second emitter formation region, and the contact formation region are repeatedly provided in this order.

9. The semiconductor device according to claim 1, wherein the first emitter region extends, in a trench array direction, from one trench portion that is in contact with the first mesa portion to another trench portion that faces the one trench portion.

10. The semiconductor device according to claim 1, wherein the trench sidewall region is in contact with a lower end of the second emitter region.

11. The semiconductor device according to claim 2, wherein a doping concentration of the trench sidewall region is lower than a doping concentration of the contact region.

12. The semiconductor device according to claim 1, wherein a doping concentration of the trench sidewall region is 1E17 cm⁻³ or more and 1E20 cm⁻³ or less.

13. The semiconductor device according to claim 1, wherein the trench sidewall region extends from one trench portion that is in direct contact with the first mesa portion to another trench portion.

14. The semiconductor device according to claim 1, comprising an accumulation region of the first conductivity type, provided above the drift region and having a doping concentration higher than that of the drift region,
wherein a lower end of the trench sidewall region is in contact with an upper end of the accumulation region.

15. The semiconductor device according to claim 1, comprising a trench contact portion extending from the front surface of the semiconductor substrate in a depth direction of the semiconductor substrate.

16. The semiconductor device according to claim 15, wherein the trench contact portion is spaced apart from the trench sidewall region.

17. The semiconductor device according to claim 15, wherein a lower end of the trench contact portion is deeper than a lower end of the second emitter region and is shallower than a lower end of the trench sidewall region.

18. The semiconductor device according to claim 15, comprising a plug region of the second conductivity type, provided above the drift region and having a doping concentration higher than that of the base region,
wherein the plug region is spaced apart from the trench sidewall region.

19. The semiconductor device according to claim 15, comprising a plug region of the second conductivity type, provided above the drift region and having a doping concentration higher than that of the base region,
wherein the plug region is provided at a lower end of the trench contact portion and is in contact with the trench sidewall region.

20. The semiconductor device according to claim 1, comprising a cathode region provided on a back surface side of the semiconductor substrate with respective to the drift region,
wherein the cathode region has:
a first cathode portion of the first conductivity type, having a doping concentration higher than that of the drift region; and
a second cathode portion of the second conductivity type, provided in contact with the first cathode portion.
